(19) United States
(12) Patent Application Publication
(10) Pub. No.: US 2026/0011383 A1
(43) Pub. Date: Jan. 8, 2026

(54) MEMORY DEVICE

(71) Applicant: Samsung Electronics Co., Ltd., Suwon-si (KR)

(72) Inventor: Dae Shik Kim, Suwon-si (KR)

(21) Appl. No.: 19/188,184

(22) Filed: Apr. 24, 2025

(30) Foreign Application Priority Data
Jul. 5, 2024 (KR) 10-2024-0088571

(51) Int. Cl. G11C 17/02

(52) U.S. Cl. CPC G11C 17/02

(57) ABSTRACT

A memory device is provided. The memory device includes a nonvolatile memory including a memory cell array, and a controller configured to control the nonvolatile memory. The memory cell array includes: a memory cell including a first magnetic tunnel junction element, an OTP (One-Time-Programmable) cell including a second magnetic tunnel junction element, and a reference cell connected to a first reference resistor for reading data for the memory cell or a second reference resistor for reading data from the OTP cell, wherein the controller is configured to set the second reference resistance, based on a first edge resistance value detected from a resistance distribution of OTP cells comprising the OTP cell or based on the first reference resistance.

### CROSS-REFERENCE TO RELATED APPLICATION(S)

This application claims priority from Korean Patent Application No. 10-2024-0088571 filed on Jul. 5, 2024 in the Korean Intellectual Property Office, and all the benefits accruing therefrom under 35 U.S.C. § 119, the contents of which in its entirety are herein incorporated by reference.

### BACKGROUND

The present disclosure relates generally to a memory device.

As an electronic device becomes faster and less power-consuming, a memory device embedded therein also requires fast read/write operations and low operating voltage. A magnetic memory device is being studied as a memory device that satisfies these requirements. The magnetic memory device is nonvolatile and capable of high-speed operation, and thus is receiving attention as a next-generation memory.

As the magnetic memory device becomes increasingly highly integrated, STT-M RAM (spin transfer torque magnetoresistive random-access memory) which stores therein information using the Spin Transfer Torque (STT) phenomenon, is being studied. The STT-MRAM may store therein information by directly applying current to a magnetic tunnel junction element to induce magnetization reversal. The highly integrated STT-M RAM provides high-speed operation and low-current operation.

In one example, an OTP (One-Time-Programmable) memory is a nonvolatile memory in which data is permanently maintained upon a single program. The OTP memory is generally used for the purpose of recording specific information only once and allowing the information to be read continuously and may be used in applications where data stability and security are important. Since the OTP memory may be programmed only once, information therein cannot be changed, thereby ensuring data integrity and stability. The OTP memory is mainly used in applications that require reliability and security. For example, the OTP memory is used to store therein information such as digital security tokens, smart cards, keys and passwords, booting codes, and production/manufacturing settings, and may be embedded as a portion of a semiconductor chip therein or may be provided as an independent chip. When the OTP memory is embedded as the portion of the chip, the OTP memory may be implemented at low cost and thus may be usefully used without affecting performance of a core logic as long as the OTP is fully compatible with a logic CM OS process.

### SUMMARY

A technical purpose of the present disclosure is to provide a memory device with improved product reliability.

Purposes according to the present disclosure are not limited to the above-mentioned purpose. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means shown in the claims and combinations thereof.

A memory device according to some embodiments of the present disclosure includes a nonvolatile memory including a memory cell array; and a controller configured to control the nonvolatile memory, wherein the memory cell array includes: a memory cell including a first magnetic tunnel junction element; an OTP (One-Time-Programmable) cell including a second magnetic tunnel junction element; and a reference cell connected to a first reference resistor having a first reference resistance for reading data for the memory cell or a second reference resistor having a second reference resistance for reading data from the OTP cell, wherein the controller is configured to set the second reference resistance, based on a first edge resistance value detected from a resistance distribution of OTP cells comprising the OTP cell or based on the first reference resistance.

A memory device according to some embodiments of the present disclosure includes a nonvolatile memory including a memory cell array; and a controller connected to the nonvolatile memory, wherein the memory cell array includes memory cells including first magnetic tunnel junction elements, and OTP cells including second magnetic tunnel junction elements, wherein the controller includes a reference resistance setting module configured to set a reference resistance for reading data of the memory cell array, wherein the reference resistance setting module is configured to: detect a first resistance value from a resistance distribution of the OTP cells programmed to the first state; to receive a second resistance value from a resistance distribution of the memory cells programmed to the first state and a resistance distribution of the memory cells programmed to a second state different from the first state; and set a reference resistance for reading data of the OTP cells, based on the first resistance value or the second resistance value.

A memory device according to some embodiments of the present disclosure includes a nonvolatile memory including a memory cell array; and a controller configured to control the nonvolatile memory, wherein the memory cell array includes: a memory cell including a first magnetic tunnel junction element connected to a first bit line, and a first cell transistor connecting the first magnetic tunnel junction element and a first source line to each other; an OTP cell including second to fourth magnetic tunnel junction elements connected to a second bit line, and second to fourth cell transistors connecting a second source line and the second magnetic tunnel junction element to each other; and a reference cell connected to a first reference resistor having a first reference resistance for reading data of the memory cell or a second reference resistor having a second reference resistance for reading data of the OTP cell, wherein the third and fourth magnetic tunnel junction elements are not connected to the second to fourth cell transistors, wherein the controller includes a reference resistance setting module configured to set the second reference resistance based on a first edge resistance value detected from a resistance distribution of OTP cells comprising the OTP cell or based on the first reference resistance.

Specific details of other embodiments are included in the detailed description and drawings.

### BRIEF DESCRIPTION OF DRAWINGS

The above and other aspects and features of the present disclosure will become more apparent by describing in detail illustrative embodiments thereof with reference to the attached drawings, wherein like reference numerals (when used) indicate corresponding elements throughout the several views, and in which:

FIG. 1 is a schematic block diagram for illustrating an electronic device according to some embodiments;

FIG. 2 is a schematic block diagram for illustrating a memory device according to some embodiments;

FIG. 3 is an example schematic circuit diagram for illustrating a memory device according to some embodiments;

FIG. 4 to FIG. 6 are example schematic cross-sectional views of a memory device according to some embodiments;

FIG. 7 to FIG. 9 are graphs conceptually illustrating setting an optimal reference resistance on a memory device according to some embodiments;

FIG. 10 is a schematic diagram for illustrating a sensing circuit according to some embodiments;

FIG. 11 is a schematic diagram for illustrating a reference resistor circuit according to some embodiments;

FIG. 12 is a diagram for illustrating a sensing circuit according to some embodiments;

FIG. 13 and FIG. 14 are example schematic cross-sectional views of a memory device according to some embodiments;

FIG. 15 and FIG. 16 are example schematic cross-sectional views of a memory device according to some embodiments; and

FIG. 17 and FIG. 18 are example schematic cross-sectional views of a memory device according to some embodiments.

### DETAILED DESCRIPTION

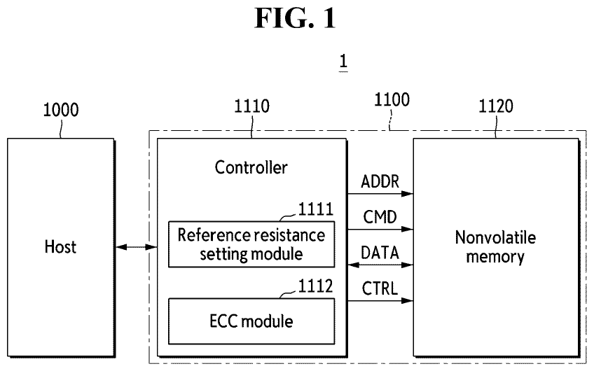

FIG. 1 is a schematic block diagram for illustrating an electronic device according to some embodiments.

Referring to FIG. 1, the electronic device 1 may include a host 1000 and a memory device 1100. In some embodiments, the host 1000 may be connected to the memory device 1100 via an interface. For example, the host 1000 may transmit a signal to the memory device 1100 to control the memory device 1100. Furthermore, for example, the host 1000 may receive a signal from the memory device 1100 and process data included in the signal.

For example, the host 1000 may include a central processing unit (CPU), a controller, or an application specific integrated circuit (A SIC). Furthermore, for example, the host 1000 may include a memory chip such as DRAM (Dynamic Random Access Memory), SRAM (Static RAM), PRAM (Phase-change RAM), M RAM (Magnetoresistive RAM), FeRAM (Ferroelectric RAM), and RRAM (Resistive RAM).

The memory device 1100 may include a controller 1110 and a nonvolatile memory 1120.

The controller 1110 may write data DATA to the nonvolatile memory 1120 or read the data DATA stored in the nonvolatile memory 1120 according to a request from an external device (e.g., a host, an application program (AP), etc.). For example, the controller 1110 may transmit an address ADDR, a command CM D, and a control signal CTRL to the nonvolatile memory 1120 to write the data DATA to the nonvolatile memory 1120 or to read the data DATA stored in the nonvolatile memory 1120.

The nonvolatile memory 1120 may exchange the data DATA with the controller 1110 in response to signals received from the controller 1110. For example, the nonvolatile memory 1120 may include M RAM (Magnetic Random Access Memory), PRAM (Phase-change RAM), RRAM (Resistive RAM), etc.

However, embodiments according to the technical idea of the present disclosure are not limited thereto. The nonvolatile memory 1120 is not limited to a resistive memory and may include various nonvolatile memories such as EEPROM (Electrically Erasable and Programmable ROM), flash memory, and FRAM (Ferroelectric RAM).

The controller 1110 and the nonvolatile memory 1120 may be connected to each other via an interface or bus. The controller 1110 may access the nonvolatile memory 1120. For example, the controller 1110 may control read, write, and erase operations on the nonvolatile memory 1120. The controller 1110 may serve as an interface between the host 1000 and the nonvolatile memory 1120. The controller 1110 may drive firmware for controlling the nonvolatile memory 1120.

The controller 1110 may include a reference resistance setting module 1111 and an error correction code (ECC) module 1112. The reference resistance setting module 1111 and the error correction code module 1112 may be electrically connected to each other via their respective interfaces. Furthermore, the reference resistance setting module 1111 and the error correction code module 1112 may exchange signals including data with each other.

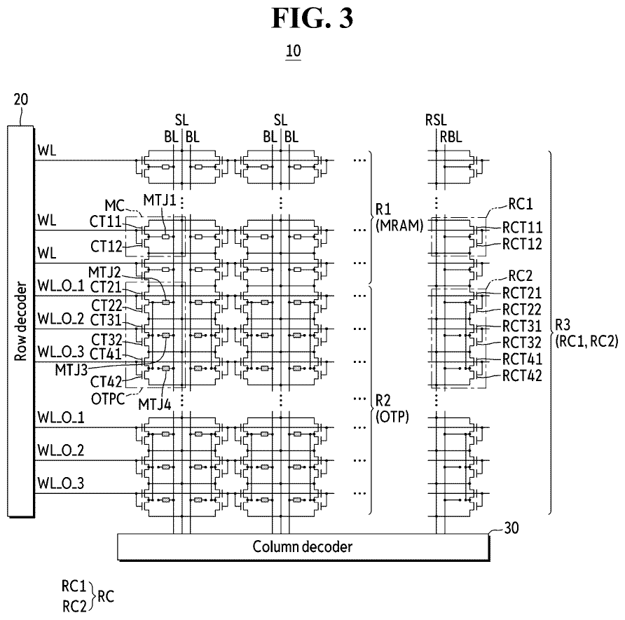

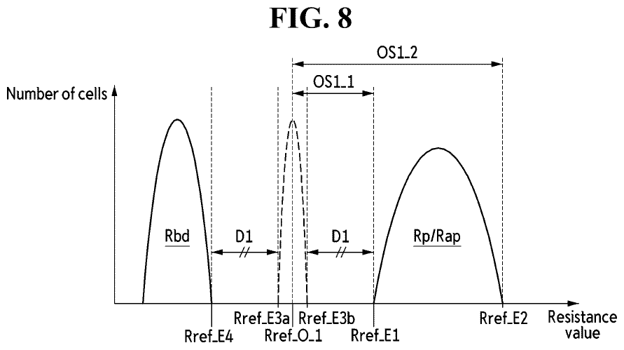

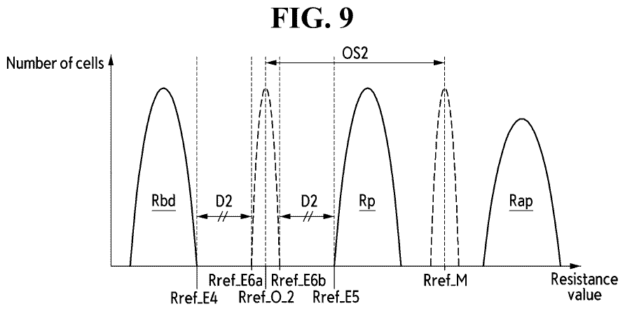

In some embodiments, the reference resistance setting module 1111 may set a first reference resistance (Rref_M in FIG. 9) as an optimal reference resistance for reading data of a memory unit cell ((MC in FIG. 3)), and a (2-1)-st reference resistance (Rref_O_1 in FIG. 8) and/or a (2-2)-nd reference resistance (Rref_O_2 in FIG. 9) as an optimal reference resistance for reading data of an OTP unit cell (OTPC in FIG. 3).

The reference resistance setting module 1111 may perform a test on the memory device through a BIST (Built-In Self-Test) logic to set the first reference resistance (Rref_M in FIG. 9), and the (2-1)-st and (2-2)-nd reference resistances (Rref_O_1 and Rref_O_2 in FIG. 8 and FIG. 9, respectively). During the test, the reference resistance setting module 1111 may generate the data DATA and transmit the data DATA to the nonvolatile memory 1120. For example, the data DATA may include information about a fail bit.

Furthermore, the reference resistance setting module 1111 may transmit the data DATA regarding the first reference resistance (Rref_M in FIG. 9) and the (2-1)-st and (2-2)-nd reference resistances (Rref_O_1 and Rref_O_2 in FIG. 8 and FIG. 9, respectively) set by performing the above test to the nonvolatile memory 1120.

The nonvolatile memory 1120 may transmit the data DATA required to perform the above test to the reference resistance setting module 1111. For example, the nonvolatile memory 1120 may transmit the data DATA regarding a resistance of a first magnetic tunnel junction element MTJ1 of the memory unit cell MC (see FIG. 3) and the data DATA regarding a resistance of a second magnetic tunnel junction element MTJ2 of the OTP unit cell OTPC (see FIG. 3) to the reference resistance setting module 1111.

The error correction code module 1112 may detect and correct an error in the data DATA read from the nonvolatile memory 1120. For example, the error correction code module 1112 may generate an error correction code on the data DATA to be stored in the nonvolatile memory 1120. The generated error correction code together with the data DATA may be stored in the nonvolatile memory 1120. Thereafter, the error correction code module 1112 may detect and correct an error in the data DATA read from the nonvolatile memory 1120 based on the stored error correction code. For example, the error correction code module 1112 has a predetermined error correction capability. For example, a fail bit of the OTP unit cell OTPC may be corrected by the error correction code module 1112.

Although not specifically shown, the controller 1110 may further include a buffer (not shown). The buffer (not shown) may temporarily store therein data provided from, for example, the components of the controller 1110, that is, the host 1000, and the nonvolatile memory 1120. Furthermore, the buffer (not shown) may provide the temporarily stored data to the components of the controller 1100, that is, the host 1000, and the nonvolatile memory 1120. For example, the buffer (not shown) may include, but is not limited to, a volatile memory such as dynamic random access memory (DRAM), static random access memory (SRAM), or may include a nonvolatile memory such as flash memory, phase-change random access memory (PRAM), magnetic random access memory (M RAM), resistive random access memory (ReRAM), and ferroelectrics random access memory (FRAM).

An example in which the buffer (not shown) is included in the controller 1110 is described above. However, embodiment according to the technical idea of the present disclosure is not limited thereto, and the buffer (not shown) may be included in the nonvolatile memory 1120.

The interface between the host 1000 and the memory device 1100 may include various communication standards, such as, for example, USB (Universal Serial Bus), MMC (multimedia card), PCI (peripheral component interconnection), PCI-E (PCI-express), ATA (Advanced Technology Attachment), Serial-ATA, Parallel-ATA, SCSI (small computer system interface), ESDI (enhanced small disk interface), IDE (Integrated Drive Electronics), and Firewire.

The memory device 1100 may include, for example, a PC card (PCMCIA: personal computer memory card international association), a compact flash card (CF), a smart media card (SM, SMC), a memory stick, a multimedia card (MMC, RS-MMC, MMCmicro), an SD (Secure Digital) card (SD, miniSD, microSD, SDHC), a universal flash memory device (UFS), etc. In addition, the memory device 1100 may include a solid state drive (SSD) integrated into a single semiconductor device.

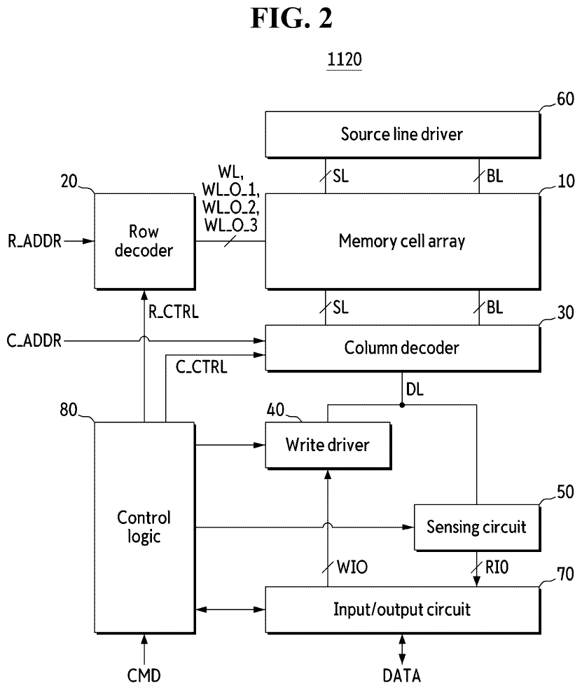

FIG. 2 is a schematic block diagram for illustrating a memory device according to some embodiments.

Referring to FIG. 2, the nonvolatile memory 1120 according to some embodiments may include a memory cell array 10, a row decoder 20, a column decoder 30, a write driver 40, a sensing circuit 50, a source line driver 60, an input/output circuit 70, and a control logic 80.

The memory cell array 10 may include a plurality of word lines WL, WL_O_1, WL_O_2, and WL_O_3, a plurality of bit lines BL, and source lines SL. Memory cells (e.g., the memory unit cell MC and the OTP unit cell OTPC of FIG. 3) may be connected to points where the word lines WL, WL_O_1, WL_O_2, and WL_O_3 and the bit lines BL intersect each other. Each of the memory cells may be configured to store data therein. The memory cell may include, for example, a variable resistance element in which a value of stored data (i.e., logic state) is determined based on a resistance value, such as a magnetic tunnel junction (MTJ) element.

For example, the memory cell may include ReRAM (Resistive RAM), PRAM (Phase Change Random Access Memory), FRAM (Ferroelectric Random Access) Memory, etc., or may include M RAM (Magnetic/Magnetoresistive Random Access Memory) such as STT-MRAM (Spin-Transfer Torque Magnetic Random Access Memory), Spin-RAM (Spin Torque Transfer Magnetization Switching RAM), and SMT-RAM (Spin Momentum Transfer RAM).

The row decoder 20 may select (or drive) a word line WL, WL_O_1, WL_O_2, or WL_O_3 connected to a memory cell on which a read operation or a program operation is performed, based on a row address R_ADDR and a row control signal R_CTRL supplied to the row decoder 20. The row decoder 20 may provide a driving voltage input from the control logic 80 to the selected word line.

The column decoder 30 may select a bit line BL and/or a source line SL connected to a memory cell on which a read operation or a program operation is performed, based on a column address C_ADDR and a column control signal C_CTRL supplied to the column decoder 30. The column decoder 30 may connect the selected bit line BL and source line SL to a data line DL.

The write driver 40 may apply a program voltage (or write current) to the memory cell selected by the row decoder 20 and the column decoder 30 to store write data therein during a program operation. For example, during the program operation, the write driver 40 may control a voltage of the data line DL based on write data DATA input from the input/output circuit 70 through a write input/output line WIO to store the write data DATA in the selected memory cell.

During a read operation, the sensing circuit 50 may detect a signal output through the data line DL and determine a value of the data stored in the memory cell based on the detected signal. The sensing circuit 50 may be connected to the column decoder 30 via the data line DL and to the input/output circuit 70 via a read input/output line RIO. The sensing circuit 50 may input detected read data DATA to the input/output circuit 70 via the read input/output line RIO.

The source line driver 60 may apply a specific voltage level to the source line SL under the control of the control logic 80. For example, the source line driver 60 may receive a voltage for driving the source line SL from the control logic 80.

The input/output circuit 70 may transmit the write data DATA input from an external source to the write driver 40 and output the read data DATA input from the sensing circuit 50 to the external source.

The control logic 80 may control all operations of the magnetic memory device. For example, the control logic 80 may control the row decoder 20, the column decoder 30, the write driver 40, the sensing circuit 50, the source line driver 60, the input/output circuit 70, etc. In one example, the control logic 80 may operate in response to a command CM D or control signals input from an external source. The command CM D may include a read command, a write command, etc.

FIG. 3 is an example schematic circuit diagram for illustrating a memory device according to some embodiments.

Referring to FIG. 3, in some embodiments, the memory cell array 10 includes a plurality of memory cells MC and OTPC arranged along a row direction and a column direction. The row direction and column direction may intersect one another. For example, the row direction may be perpendicular to the column direction. The plurality of memory cells MC and OTPC includes a plurality of memory unit cells MC and a plurality of OTP unit cells OTPC.

The plurality of memory unit cells MC may be connected to the first word lines WL, the bit lines BL, and the source lines SL. Each memory unit cell MC may include the first magnetic tunnel junction element MTJ1 and a first cell transistor CT11 and CT12.

The memory unit cell MC can be programmed multiple times. The memory unit cell MC may be switched between two resistance states under an electrical pulse applied to the first magnetic tunnel junction element MTJ1. The memory unit cell MC may be used as an M RAM.

In some embodiments, the memory unit cell MC may have a structure in which a plurality of cell transistors CT11 and CT12 are connected to one magnetic tunnel junction element MTJ1. For example, the memory unit cell MC may include two cell transistors CT11 and CT12. The number of cell transistors included in the memory unit cell MC is not limited thereto and may vary.

One end of the first magnetic tunnel junction element MTJ1 is connected to the bit line BL, and the other end of the first magnetic tunnel junction element MTJ1 is connected to one end of the (1-1)-st cell transistor CT11 and one end of the (1-2)-nd cell transistor CT12. The other end of the (1-1)-st cell transistor CT11 and the other end of the (1-2)-nd cell transistor CT12 are connected to the source line SL. A gate electrode of the (1-1)-st cell transistor CT11 and a gate electrode of the (1-2)-nd cell transistor CT12 may be connected to the first word line WL. The (1-1)-st cell transistor CT11 and the (1-2)-nd cell transistor CT12 may be turned on or off based on a signal or voltage provided thereto via the first word line WL.

The plurality of OTP unit cells OTPC may be connected to the second to fourth word lines WL_O_1, WL_O_2, and WL_O_3, the bit lines BL, and the source lines SL. Each OTP unit cell OTPC may include the second magnetic tunnel junction element MTJ2, a second cell transistor CT21 and CT22, a third magnetic tunnel junction element MTJ3, a third cell transistor CT31 and CT32, a fourth magnetic tunnel junction element MTJ4, and a fourth cell transistor CT41 and CT42.

The OTP unit cell OTPC can be programmed only once. The programmed second magnetic tunnel junction element MTJ2 may have an irreversible resistance state. The OTP unit cell OTPC may be used as the OTP memory.

According to some embodiments, the OTP unit cell OTPC may have a structure in which a plurality of cell transistors CT21, CT22, CT31, CT32, CT41 and CT42 are connected to one magnetic tunnel junction element MTJ2. For example, the OTP unit cell OTPC may include six cell transistors CT21, CT22, CT31, CT32, CT41 and CT42. The second cell transistor CT21 and CT22, the third cell transistor CT31 and CT32, and the fourth cell transistor CT41 and CT42 may be connected to each other in parallel. The number of cell transistors included in the OTP unit cell OTPC is not limited thereto and may vary.

One end of the second magnetic tunnel junction element MTJ2 is connected to the bit line BL, and the other end of the second magnetic tunnel junction element MTJ2 is connected to one end of the (2-1)-st cell transistor CT21 and one end of the (2-2)-nd cell transistor CT22. The other end of the (2-1)-st cell transistor CT21 and the other end of the (2-2)-nd cell transistor CT22 are connected to the source line SL. A gate electrode of the (2-1)-st cell transistor CT21 and a gate electrode of the (2-2)-nd cell transistor CT22 may be connected to the second word line WL_O_1. The (2-1)-st cell transistor CT21 and the (2-2)-nd cell transistor CT22 may be turned on or off based on a signal or voltage provided thereto via the second word line WL_O_1.

One end of the third magnetic tunnel junction element MTJ3 is connected to the bit line BL. The other end of the third magnetic tunnel junction element MTJ3 is not connected to one end of the (3-1)-st cell transistor CT31 and one end of the (3-2)-nd cell transistor CT32, and the third magnetic tunnel junction element MTJ3 is electrically isolated from the third cell transistor CT31 and CT32. One end of the (3-1)-st cell transistor CT31 and one end of the (3-2)-nd cell transistor CT32 are connected to the other end of the second magnetic tunnel junction element MTJ2. The other end of the (3-1)-st cell transistor CT31 and the other end of the (3-2)-nd cell transistor CT32 are connected to the source line SL. A gate electrode of the (3-1)-st cell transistor CT31 and a gate electrode of the (3-2)-nd cell transistor CT32 may be connected to the third word line WL_O_2. The (3-1)-st cell transistor CT31 and the (3-2)-nd cell transistor CT32 may be turned on or off based on a signal or voltage provided thereto via the third word line WL_O_2.

One end of the fourth magnetic tunnel junction element MTJ4 is connected to the bit line BL, and the other end of the fourth magnetic tunnel junction element MTJ4 is not connected to one end of the (4-1)-st cell transistor CT41 and one end of the (4-2)-nd cell transistor CT42. The fourth magnetic tunnel junction element MTJ4 is electrically isolated from the fourth cell transistors CT41 and CT42. One end of the (4-1)-st cell transistor CT41 and one end of the (4-2)-nd cell transistor CT42 are connected to the other end of the second magnetic tunnel junction element MTJ2. The other end of the (4-1)-st cell transistor CT41 and the other end of the (4-2)-nd cell transistor CT42 are connected to the source line SL. A gate electrode of the (4-1)-st cell transistor CT41 and a gate electrode of the (4-2)-nd cell transistor CT42 may be connected to the fourth word line WL_O_3. The (4-1)-st cell transistor CT41 and the (4-2)-nd cell transistor CT42 may be turned on or off based on a signal or voltage provided thereto via the fourth word line WL_O_3.

The third and fourth magnetic tunnel junction elements MTJ3 and MTJ4 may be dummy magnetic tunnel junction elements. The third and fourth magnetic tunnel junction elements MTJ3 and MTJ4 may be unused magnetic tunnel junction elements.

The pair of the second magnetic tunnel junction element MTJ2 and the second cell transistor CT21 and CT22, the pair of the third magnetic tunnel junction element MTJ3 and the third cell transistor CT31 and CT32, and the pair of the fourth magnetic tunnel junction element MTJ4 and the fourth cell transistor CT41 and CT42 of the OTP unit cell OTPC, and the pair of the first magnetic tunnel junction element MTJ1 and the first cell transistor CT11 and CT12 of the memory unit cell MC may be arranged in the memory cell array 10 so as to constitute a repetition unit.

Each of the first to fourth cell transistors CT11, CT12, CT21, CT22, CT31, CT32, CT41 and CT42 may include at least one of, for example, a diode, a PNP bipolar transistor, an NPN bipolar transistor, an NM OS field effect transistor, and a PM OS field effect transistor.

In some embodiments, the memory cell array 10 may include a first area R1 used as MRAM, a second area R2 used as the OTP memory and a third area R3. A plurality of memory unit cells MC are arranged in the first area R1, a plurality of OTP unit cells OTPC are arranged in the second area R2, and a plurality of reference cells RC1 and RC2 are arranged in the third area R3.

In some embodiments, memory unit cells MC constituting one column and memory unit cells MC constituting another column may share one source line SL. OTP unit cells OTPC constituting one column and OTP unit cells OTPC constituting another column may share one source line SL.

In some embodiments, a read path and a write path of the OTP unit cell OTPC may be isolated from each other. Some of the second to fourth cell transistors CT21, CT22, CT31, CT32, CT41 and C42 of the OTP unit cell OTPC may be used during a read operation of the OTP unit cell OTPC, and the remainder thereof may be used during a write operation of the OTP unit cell OTPC.

For example, the second cell transistor CT21 and CT22 connected to the second word line WL_O_1 may be used during the read operation of the OTP unit cell OTPC, and the third cell transistor CT31 and CT32 connected to the third word line WL_O_2 and the fourth cell transistor CT41 and CT42 connected to the fourth word line WL_O_3 may be used during the write operation of the OTP unit cell OTPC.

For example, the third word line WL_O_2 and the fourth word line WL_O_3 may be connected to each other. The third word line WL_O_2 and the fourth word line WL_O_3 may be the same word line. The gate of the third cell transistor CT31 and CT32 and the gate of the fourth cell transistor CT41 and CT42 may operate based on the same word line voltage and may operate based on a different word line voltage from a word line voltage based on which the gate of the second cell transistor CT21 and CT22 operates.

Alternatively, the second to fourth word lines WL_O_1, WL_O_2, and WL_O_3 may be different word lines. The gate of the second cell transistor CT21 and CT22, the gate of the third cell transistor CT31 and CT32, and the gate of the fourth cell transistor CT41 and CT42 may operate based on different word line voltages.

In some embodiments, the read path and the write path of the OTP unit cell OTPC may not be isolated from each other. The second to fourth cell transistors CT21, CT22, CT31, CT32, CT41 and C42 of the OTP unit cell OTPC may be used during both the read and write operations of the OTP unit cell OTPC.

The memory cell array 10 may be electrically connected to a peripheral circuit. The peripheral circuit may include, for example, the row decoder 20, the column decoder 30, the write driver 40, the sensing circuit 50, the source line driver 60, the input/output circuit 70, and the control logic 80 of FIG. 1. The memory unit cells MC and the OTP unit cells OTPC may be electrically connected to the peripheral circuit. That is, the memory unit cells MC and the OTP unit cells OTPC may share the peripheral circuit.

In some embodiments, the OTP unit cells OTPC may be connected to specific word lines (e.g., the second to fourth word lines WL_O_1, WL_O_2, and WL_O_3).

The first area R1 may include the first word lines WL and memory unit cells MC connected to the first word lines WL. The second area R2 may include the second word lines WL_O_1 and OTP unit cells OTPC connected to the third word lines WL_O_2. Only memory unit cells MC may be connected to the first word line WL, and only OTP unit cells OTPC may be connected to the second to fourth word lines WL_O_1, WL_O_2, and WL_O_3. The memory unit cells MC and the OTP unit cells OTPC may be connected to one bit line BL.

The arrangement of the first area R1 and the second area R2 within the memory cell array 10 may vary. For example, the second area R2 may constitute a peripheral area of the memory cell array 10. The OTP unit cells OTPC may be connected to the second to fourth word lines WL_O_1, WL_O_2, and WL_O_3 disposed in the peripheral area of the memory cell array 10.

Since the OTP unit cells OTPC are connected to the specific word lines (for example, the second to fourth word lines WL_O_1, WL_O_2, and WL_O_3), not only the memory unit cells MC but also the OTP unit cells OTPC may be subjected to error correction based on the ECC (Error Correction Code), or an alternative error correction scheme.

In addition, during the write operation of the OTP unit cell OTPC, the voltage applied to the second to fourth word lines WL_O_1, WL_O_2, and WL_O_3 may increase such that the resistance of each of the second to fourth cell transistors CT21, CT22, CT31, CT32, CT41, and C42 of the OTP unit cell OTPC may be reduced without stressing the memory unit cell MC.

The memory cell array 10 may include reference cells RC arranged along the row direction and the column direction. The reference cells RC may include the first reference cell RC1 and the second reference cell RC2. A first reference resistor Rref_M or a second reference resistor Rref_O as described below may be selectively connected to the reference cell RC to read data of each of the memory unit cell MC and the OTP unit cell OTPC.

The first reference cell RC1 may be connected to the first word line WL, a reference bit line RBL, and a reference source line RSL. The second reference cell RC2 may be connected to the second to fourth word lines WL_O_1, WL_O_2, and WL_O_3, the reference bit line RBL, and the reference source line RSL.

The first reference cell RC1 may include a first reference cell transistor RCT11 and RCT12 connected to the first word line WL. The second reference cell RC2 may include a second reference cell transistor RCT21 and RCT22 connected to the second word line WL_O_1, a third reference cell transistor RCT31 and RCT32 connected to the third word line WL_O_2, and a fourth reference cell transistor RCT41 and RCT42 connected to the fourth word line WL_O_3.

Gates of the first reference cell transistor RCT11 and RCT12 and the first cell transistor CT11 and CT12 arranged in the row direction may be commonly connected to the first word line WL. Gates of the second reference cell transistor RCT21 and RCT22 and the second cell transistor CT21 and CT22 arranged in the row direction may be commonly connected to the second word line WL_O_1. Gates of the third reference cell transistor RCT31 and R CT32 and the third cell transistor CT31 and CT32 arranged in the row direction may be commonly connected to the third word line WL_O_2. Gates of the fourth reference cell transistor RCT41 and RCT42 and the fourth cell transistor CT41 and CT42 arranged in the row direction may be commonly connected to the fourth word line WL_O_3.

One end of the (2-1)-st reference cell transistor RCT21 and one end of the (2-2)-nd reference cell transistor RCT22 are connected to the reference bit line RBL. The other end of the (2-1)-st reference cell transistor RCT21 and the other end of the (2-2)-nd reference cell transistor RCT22 are connected to the reference source line SL. A gate electrode of the (2-1)-st reference cell transistor RCT21 and a gate electrode of the (2-2)-nd reference cell transistor RCT22 may be connected to the second word line WL_O_1.

One end of the (3-1)-st reference cell transistor RCT31 and one end of the (3-2)-nd reference cell transistor RCT32 are connected to the reference bit line RBL. The other end of the (3-1)-st reference cell transistor RCT31 and the other end of the (3-2)-nd reference cell transistor RCT32 are connected to the reference source line RSL. A gate electrode of the (3-1)-st reference cell transistor RCT31 and a gate electrode of the (3-2)-nd reference cell transistor RCT32 may be connected to the third word line WL_O_2.

One end of the (4-1)-st reference cell transistor RCT41 and one end of the (4-2)-nd reference cell transistor RCT42 are connected to the reference bit line RBL. The other end of the (4-1)-st reference cell transistor RCT41 and the other end of the (4-2)-nd reference cell transistor RCT42 are connected to the reference source line RSL. A gate electrode of the (4-1)-st reference cell transistor RCT41 and a gate electrode of the (4-2)-nd reference cell transistor RCT42 may be connected to the fourth word line WL_O_3.

The first and second reference cells RC1 and RC2 may be connected to different word lines WL, WL_O_1, WL_O_2, and WL_O_3.

In one example, the number of reference cell transistors included in the first and second reference cells RC1 and RC2 is not limited thereto and may vary.

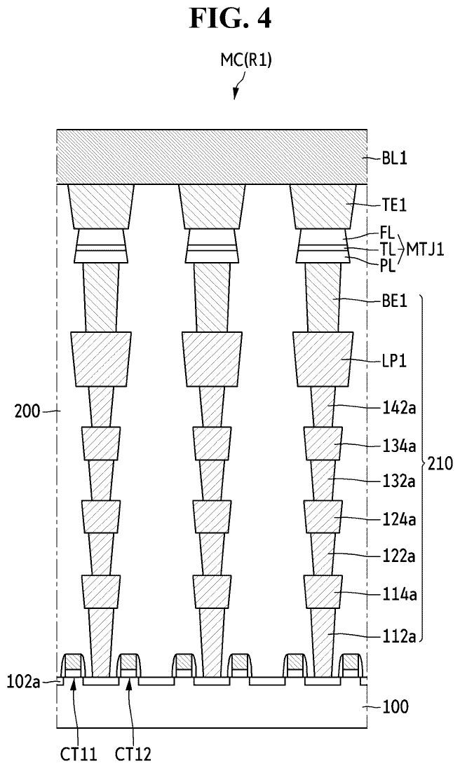

FIGS. 4 to 6 are example schematic cross-sectional views of a memory device according to some embodiments.

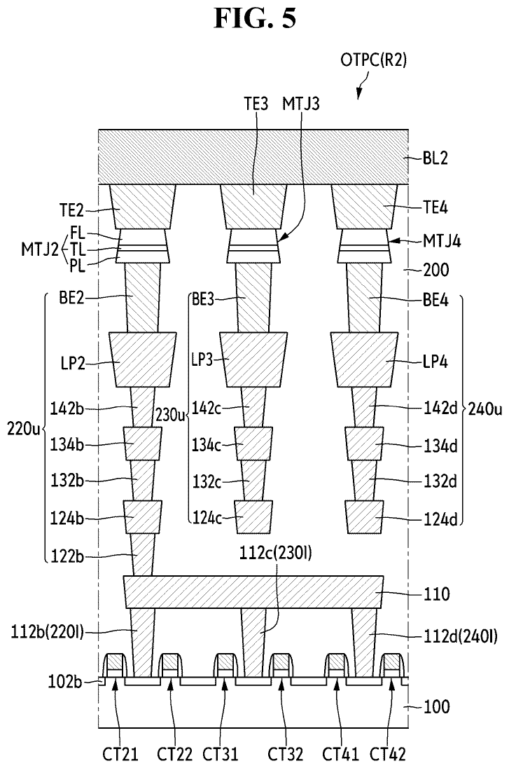

FIG. 4 is an example schematic cross-sectional view of a portion including three memory unit cells MC connected to one bit line in FIG. 3, and FIG. 5 is an example schematic cross-sectional view of a portion including one OTP unit cell OTPC connected to one bit line in FIG. 2. For convenience of illustration, the source line of FIG. 2 is omitted in FIG. 3 and FIG. 4.

Referring to FIG. 3 to FIG. 5, the memory device according to some embodiments may include a substrate 100, the first to fourth cell transistors CT11, CT12, CT21, CT22, CT31, CT32, CT41 and CT42, an insulating film 200, a wiring structure 210, first to third lower wiring structures 220l, 230l, and 240l, first to third upper wiring structure 220u, 230u, and 240u, the first to fourth magnetic tunnel junction elements MTJ1, MTJ2, MTJ3, and MTJ4, first to fourth upper electrodes TE1, TE2, TE3, and TE4, first to fourth lower electrodes BE1, BE2, BE3, and BE4, first to fourth landing pads LP1, LP2, LP3, and LP4, and first and second bit lines BL1 and BL2. The bit line BL of FIG. 3 may include the first bit line BL1 connected to the memory unit cell MC and the second bit line BL2 connected to the OTP unit cell OTPC.

Each memory unit cell MC may include the first cell transistor CT11 and CT12, the wiring structure 210, the first magnetic tunnel junction element MTJ1, and the first upper electrode TE1.

Each OTP unit cell OTPC may include the second to fourth cell transistors CT21, CT22, CT31, CT32, CT41 and CT42, a connection wiring 110, the first to third lower wiring structures 220l, 230l, and 240l, the first to third upper wiring structures 220u, 230u, and 240u, the second to fourth magnetic tunnel junction elements MTJ2, MTJ3, and MTJ4, and the second to fourth upper electrodes TE2, TE3, and TE4.

The substrate 100 may be, for example, a silicon substrate, a gallium arsenide substrate, a silicon germanium substrate, a ceramic substrate, a quartz substrate, or a glass substrate for a display, or may be a SOI (Semiconductor On Insulator) substrate. However, embodiments of the present disclosure are not limited thereto.

The first to fourth cell transistors CT11, CT12, CT21, CT22, CT31, CT32, CT41 and CT42 may be formed on the substrate 100. A first impurity area 102a may be formed in the substrate 100 (e.g., proximate an upper surface of the substrate 100) and on each of both opposing sides of the first cell transistor CT11 and CT12. The first impurity area 102a may be provided as a source area or a drain area of the first cell transistor CT11 and CT12. A second impurity area 102b may be formed in the substrate 100 (e.g., proximate the upper surface of the substrate 100) and on each of both opposing sides of each of the second to fourth cell transistors CT21, CT22, CT31, CT32, CT41 and CT42. The second impurity area 102b may be provided as a source area or a drain area of each of the second to fourth cell transistors CT21, CT22, CT31, CT32, CT41 and CT42. Each of the first impurity area 102a and the second impurity area 102b may include N-type or P-type impurities.

The insulating film 200 may be formed on the substrate 100. The insulating film 200 may cover the first cell transistor CT11 and CT12. The term “cover” (or “covers,” or like terms), as may be used herein, is intended to broadly refer to an element, structure or layer that is on or over another element, structure or layer, either directly or with one or more other intervening elements, structures or layers therebetween. The connection wiring 110, the first to third lower wiring structures 220l, 230l, and 240l, the first to third upper wiring structures 220u, 230u, and 240u, the first to fourth magnetic tunnel junction elements MTJ1, MTJ2, MTJ3, and MTJ4, and the first to fourth upper electrodes TE1, TE2, TE3, and TE4 may be formed within the insulating film 200. The insulating film 200 may include, for example, silicon oxide or silicon oxynitride. The insulating film 200 may have a multi-film (i.e., multi-layer) structure.

The first to fourth magnetic tunnel junction elements MTJ1, MTJ2, MTJ3 and MTJ4 may be formed on the substrate 100. Each of the first to fourth magnetic tunnel junction elements MTJ1, MTJ2, MTJ3 and MTJ4 may be formed at the same vertical level from the substrate 100; that is, an upper surface of each of the first to fourth magnetic tunnel junction elements MTJ1, MTJ2, MTJ3 and MTJ4 may be coplanar.

The wiring structure 210, the first to third lower wiring structures 220l, 230l, and 240l, and the first to third upper wiring structures 220u, 230u, and 240u may be formed on the substrate 100.

The wiring structure 210 may connect the substrate 100 and the first magnetic tunnel junction element MTJ1 to each other. The term “connect” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The wiring structure 210 may include, for example, a (1-1)-st via 112a, a (1-1)-st wiring 114a, a (2-1)-st via 122a, a (2-1)-st wiring 124a, a (3-1)-st via 132a, a (3-1)-st wiring 134a, a (4-1)-st via 142a, the first landing pad LP1 and the first lower electrode BE1 on the substrate 100. The (1-1)-st via 112a may be connected to the first impurity area 102a. The (2-1)-st via 122a may connect the (1-1)-st wiring 114a and the (2-1)-st wiring 124a to each other. The (3-1)-st via 132a may connect the (2-1)-st wiring 124a and the (3-1)-st wiring 134a to each other. The (4-1)-st via 142a may connect the (3-1)-st wiring 134a and the first landing pad LP1 to each other. The first lower electrode BE1 may connect the first landing pad LP1 and the first magnetic junction element MTJ1 to each other.

The first upper electrode TE1 may be formed on the first magnetic tunnel junction element MTJ1. The first upper electrode TE1 may be electrically connected to the first magnetic tunnel junction element MTJ1. The first bit line BL1 may be formed on the first upper electrode TE1. The first bit line BL1 may be connected to the first upper electrode TE1. The first magnetic tunnel junction element MTJ1 may be electrically connected to the first cell transistor CT11 and CT12 via the wiring structure 210 and may be electrically connected to the first bit line BL1 via the first upper electrode TE1.

The connection wiring 110 may be disposed on the substrate 100. In some embodiments, the connection wiring 110 may be disposed at the lowest vertical metal level among the wirings. The connection wiring 110 may be the wiring closest to the substrate 100. The second to fourth cell transistors CT21, CT22, CT31, CT32, CT41 and CT42 may be electrically connected to each other via the connection wiring 110 as the wiring closest to the substrate 100. The connection wiring 110 may be formed at the same vertical level as that of the (1-1)-st wiring 114a from the substrate 100. That is, under the second to fourth magnetic tunnel junction elements MT2, MTJ3, and MT4, the wirings disposed at the same vertical level as that of the (1-1)-st wiring 114a may be directly connected to each other.

The third and fourth magnetic tunnel junction elements MTJ3 and MTJ4 may be isolated from the connection wiring 110 at a vertical level higher than that of the connection wiring 110, relative to the upper surface of the substrate 100 as a reference layer. In some embodiments, a via at the same vertical level as that of a via that directly contacts the connection wiring 110 may be omitted in an area between each of the third and fourth magnetic tunnel junction elements MTJ3 and MTJ4 and the connection wiring 110. For example, a via at the same vertical level as a vertical level of the (2-2)-nd via 122b may be omitted in each of an area between the third magnetic tunnel junction element MTJ3 and the connection wiring 110 and an area between the fourth magnetic tunnel junction element MTJ4 and the connection wiring 110.

A vertical metal level at which the connection wiring 110 is positioned and a vertical metal level at which the via (or the wiring) omitted in each of the area between the third magnetic tunnel junction element MTJ3 and the connection wiring 110 and the area between the fourth magnetic tunnel junction element MTJ4 and the connection wiring 110 is positioned may vary depending on the design of the magnetic memory device. Regardless of the level at which a via (or wiring) is omitted, the third and fourth magnetic tunnel junction elements MTJ3 and MTJ4 are electrically disconnected from the connection wiring 110.

The first to third lower wiring structures 220l, 230l, and 240l may be spaced apart from each other in the horizontal direction. Each of the first to third lower wiring structures 220l, 230l, and 240l may connect the substrate 100 and the connection wiring 110 to each other.

The first lower wiring structure 220l may include a (1-2)-nd via 112b. The second lower wiring structure 230l may include a (1-3)-rd via 112c. The third lower wiring structure 240l may include a (1-4)-th via 112d. Each of the (1-2)-nd to (1-4)-th vias 112b, 112c, and 112d may connect the second impurity area 102b and the connection wiring 110 to each other. The (1-1)-st to (1-4)-th vias 112a, 112b, 112c, and 112d may be formed at the same vertical level from the substrate 100.

The first to third upper wiring structures 220u, 230u, and 240u may be formed on the connection wiring 110. The first to third upper wiring structures 220u, 230u, and 240u may be spaced apart from each other in the horizontal direction. Each of the first to third upper wiring structures 220u, 230u, and 240u may be connected to a respective one of the second to fourth magnetic tunnel junction elements MTJ2, MTJ3, and MTJ4.

The first upper wiring structure 220u may be disposed between the connection wiring 110 and the second magnetic tunnel junction element MTJ2 in the vertical direction. The first upper wiring structure 220u may electrically connect the connection wiring 110 and the second magnetic tunnel junction element MTJ2 to each other. The first upper wiring structure 220u may include, for example, a (2-2)-nd via 122b, a (2-2)-nd wiring 124b, a (3-2)-nd via 132b, a (3-2)-nd wiring 134b, a (4-2)-nd via 142b, the second landing pad LP2, and the second lower electrode BE2 sequentially stacked on the connection wiring 110 in the vertical direction. The (2-2)-nd via 122b may electrically connect the connection wiring 110 to the (2-2)-nd wiring 124b. The (3-2)-nd via 132b may connect the (2-2)-nd wiring 124b to the (3-2)-nd wiring 134b. The (4-2)-nd via 142b may connect the (3-2)-nd wiring 134b to the second landing pad LP2. The second lower electrode BE2 may connect the second landing pad LP2 to the second magnetic junction element MTJ2.

The second upper wiring structure 230u may be disposed between the connection wiring 110 and the third magnetic tunnel junction element MTJ3 in the vertical direction. The second upper wiring structure 230u may be spaced apart from the connection wiring 110 and may be connected to the third magnetic tunnel junction element MTJ3. The second upper wiring structure 230u may include, for example, a (2-3)-rd wiring 124c, a (3-2)-rd via 132c, a (3-2)-rd wiring 134c, a (4-2)-rd via 142c, the third landing pad LP3 and the third lower electrode BE3 sequentially stacked on the connection wiring 110 in the vertical direction. The (2-3)-rd wiring 124c may be spaced apart from the connection wiring 110. The (2-3)-rd wiring 124c may not be in direct contact with the connection wiring 110. The (3-2)-rd via 132c may connect the (2-3)-rd wiring 124c to the (3-2)-rd wiring 134c. The (4-2)-rd via 142c may connect the (3-2)-rd wiring 134c to the third landing pad LP3. The third lower electrode BE3 may connect the third landing pad LP3 to the third magnetic junction element MTJ3.

The third upper wiring structure 240u may be disposed between the connection wiring 110 and the fourth magnetic tunnel junction element MTJ4 in the vertical direction. The third upper wiring structure 240u may be spaced apart from the connection wiring 110 and may be connected to the fourth magnetic tunnel junction element MTJ4. The third upper wiring structure 240u may include, for example, a (2-4)-th wiring 124d, a (3-4)-th via 132d, a (3-4)-th wiring 134d, a (4-4)-th via 142d, the fourth landing pad LP4 and the fourth lower electrode BE4 sequentially stacked on the connection wiring 110 in the vertical direction. The (2-4)-th wiring 124d may be spaced apart from the connection wiring 110. The (2-4)-th wiring 124d may not be in direct contact with the connection wiring 110. The (3-4)-th via 132d may connect the (2-4)-th wiring 124d to the (3-4)-th wiring 134d. The (4-4)-th via 142d may connect the (3-4)-th wiring 134d to the fourth landing pad LP4. The fourth lower electrode BE4 may connect the fourth landing pad LP4 to the fourth magnetic junction element MTJ4.

The (2-1)-st via 122a and the (2-2)-nd via 122b may be formed at the same vertical level from the substrate 100. The (2-1)-st to (2-4)-th wirings 124a, 124b, 124c, and 124d may be formed at the same vertical level from the substrate 100. The (3-1)-st to (3-4)-th via 132a, 132b, 132c, and 132d may be formed at the same vertical level from the substrate 100. The (3-1)-st to (3-4)-th wirings 134a, 134b, 134c, and 134d may be formed at the same vertical level from the substrate 100. The (4-1)-st to (4-4)-th vias 142a, 142b, 142c, and 142d may be formed at the same vertical level from the substrate 100. The first to fourth landing pads LP1, LP2, LP3, and LP4 may be formed at the same vertical level from the substrate 100. The first to fourth lower electrodes BE1, BE2, BE3, and BE4 may be formed at the same vertical level from the substrate 100.

Each of the second to fourth upper electrodes TE2, TE3, and TE4 may be formed on a respective one of the second to fourth magnetic tunnel junction elements MTJ2, MTJ3, and MTJ4. Each of the second to fourth upper electrodes TE2, TE3, and TE4 may be electrically connected to each of the second to fourth magnetic tunnel junction elements MTJ2, MTJ3, and MTJ4. The first to fourth upper electrodes TE1, TE2, TE3, and TE4 may be formed at the same vertical level from the substrate 100.

The second bit line BL2 may be formed on the second to fourth upper electrodes TE2, TE3, and TE4. The second bit line BL2 may be electrically connected to the second to fourth upper electrodes TE2, TE3, and TE4. The first and second bit lines BL1 and BL2 may be formed at the same vertical level from the substrate 100.

The second magnetic tunnel junction element MTJ2 may be electrically connected to the second to fourth cell transistors CT21, CT22, CT31, CT32, CT41 and CT42 via the first upper wiring structure 220u, the connection wiring 110, and the first to third lower wiring structures 220l, 230l, and 240l, and may be electrically connected to the second bit line BL2 via the second upper electrode TE2.

Each of the (1-1)-st to (1-4)-th vias 112a, 112b, 112c, and 112d, the (2-1)-st via 122a, the (2-2)-nd via 122b, the (2-1)-st to (2-4)-th wirings 124a, 124b, 124c, and 124d, the (3-1)-st to (3-4)-th vias 132a, 132b, 132c, and 132d, and the (4-1)-st to (4-4)-th vias 142a, 142b, 142c, and 144d may include a metal (e.g., copper). Each of the first to fourth landing pads LP1, LP2, LP3, and LP4 may include at least one of, for example, a doped semiconductor material (e.g., doped silicon), a metal (e.g., tungsten, titanium, and/or tantalum), a metal-semiconductor compound (e.g., metal silicide), and a conductive metal nitride (e.g., titanium nitride, tantalum nitride, and/or tungsten nitride). Each of the first to fourth lower electrodes BE1, BE2, BE3, BE4 may include, for example, a conductive metal nitride (e.g., titanium nitride or tantalum nitride). Each of the first to fourth upper electrodes TE1, TE2, TE3, and TE4 may include at least one of a metal (e.g., Ta, W, Ru, Ir, etc.) and a conductive metal nitride (e.g., TiN).

In some embodiments, each of the second to fourth magnetic tunnel junction elements MTJ2, MTJ3 and MTJ4 may have the same size as that of the first magnetic tunnel junction element MTJ1.

Each of the first to fourth magnetic tunnel junction elements MTJ1, MTJ2, MTJ3 and MTJ4 may include a first magnetic pattern PL, a tunnel barrier pattern TL, and a second magnetic pattern FL. The tunnel barrier pattern TL may be interposed between the first magnetic pattern PL and the second magnetic pattern FL.

One of the first magnetic pattern PL and the second magnetic pattern FL may be a reference layer having a pinned (i.e., fixed) magnetization direction regardless of an external magnetic field, and the other of the first magnetic pattern PL and the second magnetic pattern FL may be a free layer whose magnetization direction may be changed between two stable magnetization directions. For example, the first magnetic pattern PL may be the reference layer having a pinned magnetization direction, and the second magnetic pattern FL may be a free layer having a variable magnetization direction. In another example, the first magnetic pattern PL may be a free layer and the second magnetic pattern FL may be a reference layer.

In some embodiments, each of the first magnetic pattern PL and the second magnetic pattern FL may have perpendicular magnetic anisotropy (PM A). Each of the first magnetic pattern PL and the second magnetic pattern FL may have a magnetization easy axis extending in a vertical direction perpendicular to the upper surface of the substrate 100.

Each of the first magnetic pattern PL and the second magnetic pattern FL may include at least one of a perpendicular magnetic material (for example, CoFeTb, CoFeGd, CoFeDy), a perpendicular magnetic material having an L1₀ structure, CoPt having a hexagonal close packed lattice structure, and a perpendicular magnetic structure. The perpendicular magnetic material having the L1₀ structure may include, for example, FePt having an L1₀ structure, FePd having an L1₀ structure, CoPd having an L1₀ structure, or CoPt having an L1₀ structure. The perpendicular magnetic structure may include magnetic layers and non-magnetic layers that are alternately and repeatedly stacked on top of each other. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ or (CoCr/Pd)ₙ where n is the number of stacks, etc.

In some embodiments, each of the first magnetic pattern PL and the second magnetic pattern FL may have in-plane magnetic anisotropy (IM A). Each of the first magnetic pattern PL and the second magnetic pattern FL may have an easy magnetization axis extending in a horizontal (in-plane) direction (a direction parallel to the upper surface of the substrate 100).

Each of the first magnetic pattern PL and the second magnetic pattern FL having the in-plane magnetic anisotropy IM A may include a ferromagnetic material. In some embodiments, the magnetic pattern constituting the reference layer among the first magnetic pattern PL and the second magnetic pattern FL may further include an antiferromagnetic material for pinning the magnetization direction of the ferromagnetic material. For example, the ferromagnetic material of the reference layer may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12. For example, the antiferromagnetic material of the reference layer may include at least one of PtMn, IrMn, MnO, MnS, MnTe, MnF2, FeCl2, FeO, CoCl2, CoO, NiCl2, NiO, and Cr, or at least one selected from among precious metals. The precious metal may include ruthenium (Ru), rhodium (Rh), palladium (Pd), osmium (Os), iridium (Ir), platinum (Pt), gold (Au), or silver (Ag). For example, the ferromagnetic material of the free layer may include at least one of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. The magnetic pattern of the free layer may be composed of a plurality of layers.

The tunnel barrier pattern TL may include at least one material selected from, for example, oxides of magnesium (Mg), titanium (Ti), aluminum (Al), magnesium-zinc (MgZn) and magnesium-boron (MgB), and nitrides of titanium (Ti) and vanadium (V), although embodiments are not limited thereto.

The first magnetic tunnel junction element MTJ1 may store data in each memory unit cell MC based on variation in electrical resistance according to the magnetization direction of the first magnetic pattern PL and the magnetization direction of the second magnetic pattern FL.

For example, when the magnetization direction of the first magnetic pattern PL and the magnetization direction of the second magnetic pattern FL are parallel to each other, the first magnetic tunnel junction element MTJ1 has a low resistance value. In this case, data may be stored and read as logic ‘0’. Conversely, when the magnetization direction of the first magnetic pattern PL and the magnetization direction of the second magnetic pattern FL are anti-parallel to each other, the first magnetic tunnel junction element MTJ1 has a high resistance value. In this case, data may be stored and read as logic ‘1’. In another example, when the magnetization direction of the first magnetic pattern PL and the magnetization direction of the second magnetic pattern FL are parallel to each other, the data of the first magnetic tunnel junction element MTJ1 may be stored and read as logic ‘1’. When the magnetization direction of the first magnetic pattern PL and the magnetization direction of the second magnetic pattern FL are anti-parallel to each other, the data of the first magnetic tunnel junction element MTJ1 may be stored and read as logic ‘0’. The assignment of logic ‘0’ and logic ‘1’ states to the magnetization orientation (i.e., direction) of the magnetic tunnel junction element may be arbitrary.

A breakdown voltage may be applied across the first magnetic pattern PL and the second magnetic pattern FL of the second magnetic tunnel junction element MTJ2 via one programming operation to break an insulation of the tunnel barrier pattern TL between the first magnetic pattern PL and the second magnetic pattern FL such that the second magnetic tunnel junction element MTJ2 may have an irreversible resistance state. The second magnetic tunnel junction element MTJ2 in which the insulation of the tunnel barrier pattern TL is broken may be in a short-circuited state. The second magnetic tunnel junction element MTJ2 in which the insulation of the tunnel barrier pattern TL is broken has a low resistance value. In this case, the data may be stored and read as logic ‘0’. The second magnetic tunnel junction element MTJ2 in which the insulation of the tunnel barrier pattern TL is not broken has a high resistance value. In this case, the data may be stored and read as logic ‘1’.

When FIG. 4 and FIG. 5 are schematic cross-sectional views of one OTP unit cell OTPC and three memory unit cells MC connected to the same bit line of FIG. 3, the first bit line BL1 of FIG. 4 may be the same bit line as the second bit line BL2 of FIG. 5. When FIG. 4 and FIG. 5 are schematic cross-sectional views of one OTP unit cell OTPC and three memory unit cells MC connected to different bit lines of FIG. 3, respectively, the first bit line BL1 of FIG. 4 may be a different bit line from the second bit line BL2 of FIG. 5.

The memory cell array 10 of the memory device according to some embodiments includes the memory unit cells MC used as M RAM and the OTP unit cells OTPC used as the OTP memory. That is, since the memory unit cells MC and the OTP unit cells OTP are implemented in one memory cell array 10 without a separate OTP memory, a highly integrated magnetic memory device may be provided.

During the write operation of the OTP unit cell OTP, the breakdown voltage is applied to the second magnetic junction tunnel MTJ2 to cause the insulation breakdown of the tunnel barrier pattern TL of the second magnetic junction tunnel element MTJ2. The breakdown voltage has a higher value than a write voltage applied to the first magnetic junction tunnel MTJ1 during the write operation of the memory unit cell MC. This may cause stress to be applied to the memory unit cell MC.

However, in some embodiments of the memory device, the OTP unit cell OTPC includes the second to fourth cell transistors CT21, CT22, CT31, CT32, CT41 and CT42 connected in parallel with each other, a higher voltage may be applied across the second magnetic junction tunnel MTJ2. Therefore, even when the write voltage applied to the OTP unit cell OTPC is not significantly high, the insulation breakdown of the tunnel barrier pattern TL of the second magnetic junction tunnel MTJ2 may occur more easily. In addition, the stress of the memory unit cell MC due to the write voltage applied to the OTP unit cell OTPC may be reduced.

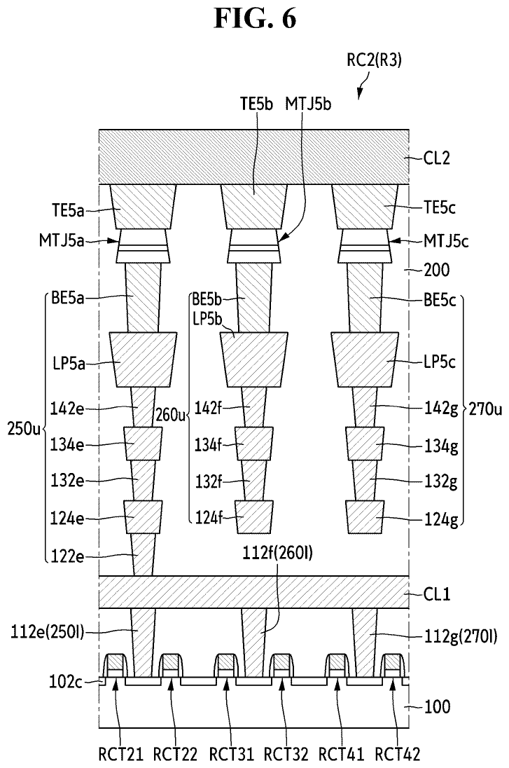

FIG. 6 is an example schematic cross-sectional view of a portion including one reference cell RC2 connected to one reference bit line RBL of FIG. 3. For convenience of illustration, the reference source line of FIG. 3 is omitted in FIG. 6.

Referring to FIG. 6, the memory device according to some embodiments may further include second to fourth reference cell transistors RCT21, RCT22, RCT31, RCT32, RCT41 and RCT42, fourth to sixth lower wiring structures 250l, 260l, and 270l, fourth to sixth upper wiring structures 250u, 260u, and 270u, 5a-th to 5c-th magnetic tunnel junction elements MTJ5a, MTJ5b, and MTJ5c, 5a-th to 5c-th upper electrodes TE5a, TE5b, and TE5c, 5a-th to 5c-th lower electrodes BE5a, BE5b, and BE5c, 5a-th to 5c-th landing pads LP5a, LP5b, and LP5c, and first and second conductive lines CL1 and CL2.

The 5a-th to 5c-th magnetic tunnel junction elements MTJ5a, MTJ5b, and MTJ5c may be formed on the substrate 100. The first to fourth magnetic tunnel junction elements MTJ1, MTJ2, MTJ3 and MTJ4 and the 5a-th to 5c-th magnetic tunnel junction elements MTJ5a, MTJ5b, and MTJ5c may be formed at the same vertical level from the substrate 100.

The reference bit line RBL of FIG. 3 may correspond to the first conductive line CL1 of FIG. 6. The second bit line BL2 of FIG. 5 may be electrically connected to the first conductive line CL1 of FIG. 6, but may not be electrically connected to the second conductive line CL2. The second to fourth reference cell transistors RCT21, RCT22, RCT31, RCT32, RCT41 and RCT42 may be electrically connected to the second bit line BL2 via the first conductive line CL1.

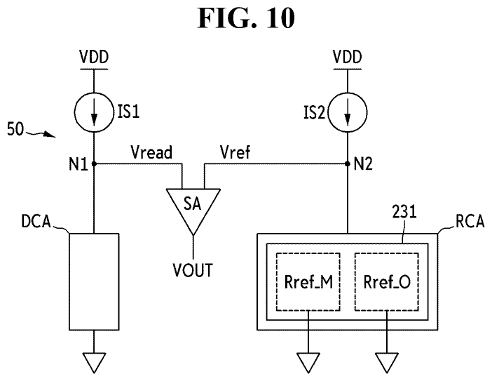

Furthermore, the 5a-th to 5c-th magnetic tunnel junction elements MTJ5a, MTJ5b, and MTJ5c and the second to fourth reference cell transistors RCT21, RCT22, RCT31, RCT32, RCT41 and RCT42 may not be electrically connected to each other. That is, the second bit line BL2 may be electrically connected to the first reference resistor Rref_M or the second reference resistor Rref_O (see FIG. 10) via the first conductive line CL1 and the fourth to sixth lower wiring structures 250l, 260l, and 270l.

The fourth to sixth lower wiring structures 250l, 260l, and 270l and the fourth to sixth upper wiring structures 250u, 260u, and 270u may be formed on the substrate 100.

The first conductive line CL1 may be disposed on the substrate 100. In some embodiments, the first conductive line CL1 may be disposed at the lowest vertical metal level among the wirings. The first conductive line CL1 may be the wiring closest to the substrate 100. The second to fourth reference cell transistors RCT21, RCT22, RCT31, RCT32, RCT41 and RCT42 may be electrically connected to each other via the first conductive line CL1 as the wiring closest to the substrate 100. The first conductive line CL1 and the connection wiring 110 may be formed at the same vertical level from the substrate 100. That is, under the 5a-th to 5c-th magnetic tunnel junction elements MTJ5a, MTJ5b, and MTJ5c, the wirings disposed at the same vertical level as a vertical level of the connection wiring 110 may be directly connected to each other.

The 5b-th and 5c-th magnetic tunnel junction elements MTJ5b, and MTJ5c may be isolated from the first conductive line CL1 at a vertical metal level higher than the first conductive line CL1.

In some embodiments, a via at the same vertical level as a vertical level of the via that directly contacts the first conductive line CL1 between the 5b-th and 5c-th magnetic tunnel junction elements MTJ5b, and MTJ5c and the first conductive line CL1 may be omitted. For example, a via at the same vertical level as a vertical level of a (2-5)-th via 122e may be omitted between the 5b-th magnetic tunnel junction element MTJ5b and the first conductive line CL1, and between the 5c-th magnetic tunnel junction element MTJ5c and the first conductive line CL1, although embodiments are not limited thereto.

The vertical metal level at which the first conductive line CL1 is disposed, and the vertical metal level at which the via (or wiring) omitted in each of the area between the 5b-th magnetic tunnel junction element MTJ5b and the first conductive line CL1, and the area between the 5c-th magnetic tunnel junction element MTJ5c and the first conductive line CL1 is disposed may vary depending on the design of the memory device.

The fourth to sixth lower wiring structures 250l, 260l, and 270l may be spaced apart from each other in the horizontal direction. Each of the fourth to sixth lower wiring structures 250l, 260l, and 270l may connect the substrate 100 to the first conductive line CL1.

The fourth lower wiring structure 250l may include a (1-5)-th via 112e. The fifth lower wiring structure 260l may include a (1-6)-th via 112f. The sixth lower wiring structure 270l may include a (1-7)-th via 112g. Each of the (1-5)-th to (1-7)-th vias 112e, 112f, and 112g may connect a third impurity area 102c formed in the substrate 100, proximate the upper surface of the substrate 100, to the first conductive line CL1. The (1-1)-th to (1-4)-th vias 112a, 112b, 112c, and 112d and the (1-5)-th to (1-7)-th vias 112e, 112f, and 112g may be formed at the same vertical level from the substrate 100; that is, an upper surface of the (1-1)-th to (1-4)-th vias 112a, 112b, 112c, and 112d and the (1-5)-th to (1-7)-th vias 112e, 112f, and 112g may be coplanar.

The fourth to sixth upper wiring structures 250u, 260u, and 270u may be formed on the first conductive line CL1. The fourth to sixth upper wiring structures 250u, 260u, and 270u may be spaced apart from each other in the horizontal direction. Each of the fourth to sixth upper wiring structures 250u, 260u, and 270u may be disposed between the first conductive line CL1 and each of the 5a-th to 5c-th magnetic tunnel junction elements MTJ5a, MTJ5b, and MTJ5c.

The fourth upper wiring structure 250u may be disposed between the first conductive line CL1 and the 5a-th magnetic tunnel junction element MTJ5a. The fourth upper wiring structure 250u may include, for example, the (2-5)-th via 122e, the (2-5)-th wiring 124e, a (3-5)-th via 132e, a (3-5)-th wiring 134e, a (4-5)-th via 142e, the 5a-th landing pad LP5a, and the 5a-th lower electrode BE5a sequentially stacked on the first conductive line CL1 in the vertical direction.

The fifth upper wiring structure 260u may be disposed between the first conductive line CL1 and the 5b-th magnetic tunnel junction element MTJ5b. The fifth upper wiring structure 260u may include, for example, a (2-6)-th wiring 124f, a (3-6)-th via 132f, a (3-6)-th wiring 134f, a (4-6)-th via 142f, the 5b-th landing pad LP5b, and the 5b-th lower electrode BE5b sequentially stacked on the first conductive line CL1 in the vertical direction. The (2-6)-th wiring 124f may be spaced apart from the first conductive line CL1. The (2-6)-th wiring 124f may not be in direct contact with the first conductive line CL1.

The sixth upper wiring structure 270u may be disposed between the first conductive line CL1 and the 5c-th magnetic tunnel junction element MTJ5c. The sixth upper wiring structure 270u may include, for example, a (2-7)-th wiring 124g, a (3-7)-th via 132g, a (3-7)-th wiring 134g, a (4-7)-th via 142g, the 5c-th landing pad LP5c, and the 5c-th lower electrode BE5c sequentially stacked on the first conductive line CL1 in the vertical direction. The (2-7)-th wiring 124g may be spaced apart from the first conductive line CL1. The (2-7)-th wiring 124g may not be in direct contact with the first conductive line CL1.

With reference to FIGS. 4-6, the (2-1)-st via 122a and the (2-2)-nd via 122b and the (2-5)-th via 122e may be formed at the same vertical level from the substrate 100. The (2-1)-st to (2-4)-th wirings 124a, 124b, 124c, and 124d and the (2-5)-th to (2-7)-th wirings 124e, 124f, and 124g may be formed at the same vertical level from the substrate 100. The (3-1)-st to (3-4)-th vias 132a, 132b, 132c, and 132d and the (3-5)-th to (3-7)-th vias 132e, 132f, and 132g may be formed at the same vertical level from the substrate 100. The (3-1)-st to (3-4)-th wirings 134a, 134b, 134c, and 134d and the (3-5)-th to (3-7)-th wirings 134e, 134f, and 134g may be formed at the same vertical level from the substrate 100. The (4-1)-st to (4-4)-th vias 142a, 142b, 142c, and 142d and the (4-5)-th to (4-7)-th vias 142e, 142f, and 142g may be formed at the same vertical level from the substrate 100. The first to fourth landing pads LP1, LP2, LP3, and LP4 and the 5a-th to 5c-th landing pads LP5a, LP5b, and LP5c may be formed at the same vertical level from the substrate 100. The first to fourth lower electrodes BE1, BE2, BE3, and BE4 and the 5a-th to 5c-th lower electrodes BE5a, BE5b, and BE5c may be formed at the same vertical level from the substrate 100.

Each of the 5a-th to 5c-th upper electrodes TE5a, TE5b, and TE5c may be formed on each of the 5a-th to 5c-th magnetic tunnel junction elements MTJ5a, MTJ5b, and MTJ5c. The 5a-th to 5c-th upper electrodes TE5a, TE5b, and TE5c may be formed at the same vertical level from the substrate 100.

The second conductive line CL2 may be formed on the 5a-th to 5c-th upper electrodes TE5a, TE5b, and TE5c. The first and second bit lines BL1 and BL2 and the second conductive line CL2 may be formed at the same vertical level from the substrate 100.

Each of the (2-5)-th via 122e, the (2-5)-th to (2-7)-th wirings 124e, 124f, and 124g, the (3-5)-th to (3-7)-th vias 132e, 132f, and 132g, the (3-5)-th to (3-7)-th wirings 134e, 134f, and 134g, and the (4-5)-th to (4-7)-th vias 142e, 142f, and 142g may include a metal (e.g., copper). Each of the 5a-th to 5c-th landing pads LP5a, LP5b, and LP5c may include at least one of, for example, a doped semiconductor material (e.g., doped silicon), a metal (e.g., tungsten, titanium, and/or tantalum), a metal-semiconductor compound (e.g., a metal silicide), or a conductive metal nitride (e.g., titanium nitride, tantalum nitride, and/or tungsten nitride), although embodiments are not limited thereto. Each of the 5a-th to 5c-th lower electrodes BE5a, BE5b, and BE5c may include, for example, a conductive metal nitride (e.g., titanium nitride or tantalum nitride). Each of the 5a-th to 5c-th upper electrodes TE5a, TE5b, and TE5c may include at least one of a metal (e.g., Ta, W, Ru, Ir, etc.) or a conductive metal nitride (e.g., TiN).

Each of the 5a-th to 5c-th magnetic tunnel junction elements MTJ5a, MTJ5b, and MTJ5c may include the first magnetic pattern PL, the tunnel barrier pattern TL, and the second magnetic pattern FL. The description of the first magnetic pattern PL, the tunnel barrier pattern TL, and the second magnetic pattern FL of each of the 5a-th to 5c-th magnetic tunnel junction elements MTJ5a, MTJ5b, and MTJ5c may refer to the description of the first magnetic pattern PL, the tunnel barrier pattern TL, and the second magnetic pattern FL of each of the first to fourth magnetic tunnel junction elements MTJ1, MTJ2, MTJ3, and MTJ4.

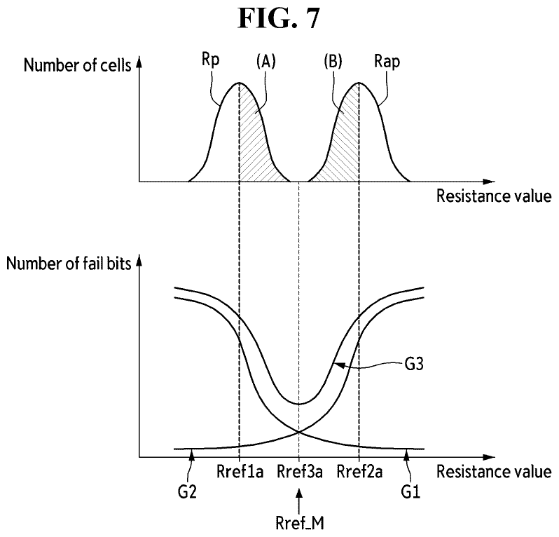

FIG. 7 to FIG. 9 are graphs conceptually illustrating setting an optimal reference resistance on a memory device according to some embodiments.

FIG. 7 is a diagram for illustrating setting the first reference resistance Rref_M for a read operation of memory unit cells MC.

Referring to FIG. 7, during a test operation on the memory device, a pre-program operation on the memory device may be performed. The pre-program operation is not for storing data, but may mean a program operation to find the optimal reference resistance to distinguish a P (parallel) state and an AP (anti-parallel) state from each other during the test phase of the memory device.

First, using the reference resistance setting module (1111 in FIG. 1), the memory unit cells MC may be programmed to the P state. A resistance distribution of the memory unit cells MC programmed to the P state may be indicated as Rp. Afterwards, using the reference resistance setting module (1111 in FIG. 1), the number of fail bits on the memory device may be counted. In this regard, the fail bit may mean a memory unit cell MC which has been programmed with specific data, but from which data different from the specific data is read.

For example, when counting the fail bits using a relatively low reference resistance value (e.g., 1a-th reference resistance Rref1a), the memory unit cells MC of an area A has programming failure and may be counted as the fail bits. Further, the number of fail bits may decrease as the reference resistance value increases from the relatively low reference resistance value (e.g., as it reaches 3a-th reference resistance Rref3a). G1 in FIG. 7 shows the tendency of the number of fail bits of the memory unit cells MC which have been programmed to the P state.

Furthermore, using the reference resistance setting module (1111 in FIG. 1), memory unit cells MC may be programmed to the AP (anti-parallel) state. The resistance distribution of memory unit cells MC programmed to the AP state may be indicted as Rap. Then, the number of fail bits on the memory device may be counted using the reference resistance setting module (1111 in FIG. 1). For example, when counting the fail bits using a relatively high reference resistance value (e.g., 2a-th reference resistance Rref2a), the memory cells in an area B has programming failure and may be counted as the fail bits. However, the number of fail bits may decrease as the reference resistance value decreases therefrom (e.g., as it reaches the 3a-th reference resistance Rref3a). G2 in FIG. 7 shows the tendency of the number of fail bits of memory unit cells MC which have been programmed to the AP state.

Afterwards, the reference resistance setting module (1111 in FIG. 1) may set the optimal reference resistance Rref_M for reading data from the memory unit cell (MC in FIG. 3) using the number of counted fail bits. For example, the reference resistance setting module (1111 in FIG. 1) may sum the number of fail bits G1 measured in the P state and the number of fail bits G2 measured in the AP state and may calculate a resistance value which minimizes the number of fail bits, i.e., the optimal reference resistance Rref_M, based on the summing result. G3 in FIG. 7 represents the sum of the number of fail bits G1 measured in the P state and the number of fail bits G2 measured in the AP state.

That is, the reference resistance Rref_M may be provided from the resistance distribution of memory unit cells MC including memory unit cell MC programmed to the P state among the memory unit cells MC and the resistance distribution of memory unit cells MC including memory unit cell MC programmed to the AP state among the memory unit cells MC.

FIG. 8 is a diagram for illustrating setting the (2-1)-st reference resistance Rref_O_1 during the read operation of the OTP unit cells OTPC.

In the graph of FIG. 8, a horizontal axis represents a resistance value of the magnetic tunnel junction element included in the memory cell array, and a vertical axis represents the number of cells having the resistance value.

First, using the reference resistance setting module (1111 in FIG. 1), the OTP unit cells OTPC may be programmed to the P (parallel) state or the AP (anti-parallel) state. Hereinafter, for the convenience of description, it is assumed that the OTP unit cells OTPC are programmed to the P state.

Thereafter, the reference resistance setting module 1111 may perform a test to detect a first edge resistance value Rref_E1 of the resistance distribution Rp of the P state of the OTP unit cell OTPC through the BIST (Built-In Self Test) logic of the memory device 1100.

The resistance distribution Rp of the P state of the OTP unit cell OTPC may have the first edge resistance value Rref_E1 adjacent to a first end of the resistance distribution Rp, and a second edge resistance value Rref_E2 that is greater than the first edge resistance value Rref_E1 and adjacent to a second end of the resistance distribution Rp.

Under the above test, the first edge resistance value Rref_E1 may be detected as a resistance value at which the number of fail bits of the OTP unit cell OTPC becomes a specific number. This first edge resistance value Rref_E1 may not be a resistance value at which the number of fail bits of the OTP unit cell OTPC is the minimum, but may mean a specific resistance value at which the fail bit occurs. Furthermore, the specific number of fail bits may mean the number of a range in which the number of fail bits may be corrected by the error correction code module (1112 in FIG. 1).

Meanwhile, fail bits may refer to bits that are likely to be judged as fail bits rather than bits that are actually judged as fail bits. For example, such bits may refer to those that deviate from the mean by approximately two standard deviations (20) based on a normal distribution. Alternatively, they may refer to bits that fall within the lower 5% range in terms of overall bit characteristics, and are thus considered to have a relatively higher likelihood of being classified as fail bits, but is not limited thereto.

Afterwards, the reference resistance setting module 1111 may set a resistance value offset by a (1-1)-st offset OS1_1 from the first edge resistance value Rref_E1 as the (2-1)-st reference resistance Rref_O_1.

That is, when the OTP unit cells OTPC are programmed to the P parallel state, the reference resistance setting module 1111 may set the resistance value offset by the (1-1)-st offset OS1_1 from the low-edge resistance value Rref_E1 of the resistance distribution Rp of the P state of the OTP unit cell OTPC as the (2-1)-st reference resistance Rref_O_1. Alternatively, the reference resistance setting module 1111 may set a resistance value offset by a (1-2)-nd offset OS1_2 from the high-edge resistance value Rref_E2 of the resistance distribution Rp of the P state of the OTP unit cell OTPC as the (2-1)-st reference resistance Rref_O_1.

When the OTP unit cells OTPC are programmed into the AP anti-parallel state, the reference resistance setting module 1111 may set a resistance value offset by the (1-1)-st offset OS1_1 from the low-edge resistance value Rref_E1 of the resistance distribution Rap of the A P state of the OTP unit cell OTPC as the (2-1)-st reference resistance Rref_O_1. Alternatively, the reference resistance setting module 1111 may set a resistance value offset by the (1-2)-nd offset OS1_2 from the high edge resistance value Rref_E2 of the resistance distribution Rap of the AP state of the OTP unit cell OTPC as the (2-1)-st reference resistance Rref_O_1.

The (1-1)-st offset OS1_1 may vary depending on the first edge resistance value Rref_E1. In other words, the (1-1)-st offset OS1_1 may be a variable based on the first edge resistance value Rref_E1. Furthermore, the (1-2)-nd offset OS1_2 may vary depending on the second edge resistance value Rref_E2.

For example, an offset D1 between a high-edge resistance value Rref_E4 in a resistance distribution Rbd of the OTP unit cell OTPC in a breakdown state and a low-edge resistance value Rref_E3a of the (2-1)-st reference resistance Rref_O_1, and the offset D1 between the first edge resistance value Rref_E1 of the OTP unit cell OTPC and a high-edge resistance value Rref_E3b of the (2-1)-st reference resistance Rref_O_1 may be equal to each other.

That is, the (1-1)-st offset OS1_1 may vary based on the first edge resistance value Rref_E1 so that a distribution of the (2-1)-st reference resistance Rref_O_1 is positioned between the resistance distribution Rbd of the second magnetic tunnel junction element MTJ2 in the breakdown state and the resistance distribution Rp in the P state thereof.

FIG. 9 is a diagram for illustrating setting the (2-2)-nd reference resistance Rref_O_2 for the read operation of OTP unit cells OTPC.

Referring to FIG. 9, the reference resistance setting module (1111 of FIG. 1) may receive information about the first reference resistance Rref_M of the memory unit cell MC from the memory cell array 10. The first reference resistance Rref_M may be set through the test process of FIG. 7 and stored in the memory cell array 10.

Thereafter, the reference resistance setting module (1111 of FIG. 1) may set a resistance value offset from the first reference resistance Rref_M by a second offset OS2 as the (2-2)-nd reference resistance Rref_O_2.

The second offset OS2 may vary depending on the first reference resistance Rref_M. In other words, the second offset OS2 may be a variable based on the first reference resistance Rref_M.

For example, an offset D2 between the high edge resistance value Rref_E4 of the resistance distribution Rbd of the OTP unit cell OTPC in the breakdown state and the low edge resistance value Rref_E6a of the (2-2)-nd reference resistance Rref_O_2 may be equal to the offset D2 between a low edge resistance value Rref_E5 of the memory unit cell MC and a high edge resistance value Rref_E6b of the (2-2)-nd reference resistance Rref_O_2.

That is, the second offset OS2 may vary based on the first reference resistance Rref_M so that a distribution of the (2-2)-nd reference resistance Rref_O_2 is positioned between the resistance distribution Rbd of the second magnetic tunnel junction element MTJ2 in the breakdown state and the resistance distribution Rp of the first magnetic tunnel junction element MTJ1 in the P state.

In order to ensure the accuracy of reading the data from the OTP unit cell OTPC, it is necessary to distinguish the resistance value of the P parallel state of the magnetic tunnel junction element and the resistance value of the insulation breakdown state thereof. For example, the resistance distribution of the P state varies greatly depending on the size of the M RAM cell, while the resistance distribution of the insulation breakdown state is almost constant. Therefore, in order to secure the read margin of the OTP unit cell OTPC, it is necessary to set the reference resistance of the OTP unit cell OTPC in consideration of the resistance distribution of the P state. In the memory device according to some embodiments, a fixed reference resistance value based on the resistance distribution of the magnetic tunnel junction element may be set as the reference resistance for reading the data from the memory cell array 10, such that the read margin of the OTP unit cell OTPC may be secured while using a reference resistor circuit having a relatively simple structure.

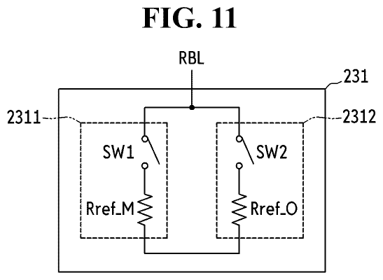

FIG. 10 is a schematic diagram for illustrating a sensing circuit according to some embodiments. FIG. 11 is a schematic diagram for illustrating a reference resistor circuit according to some embodiments.

Referring to FIG. 10 and FIG. 11, a nonvolatile memory according to some embodiments may include a data cell area DCA, a reference cell area RCA, a reference resistor circuit 231, and the sensing circuit 50.

The data cell area DCA may include the memory unit cell MC and the OTP unit cell OTPC of FIG. 3. The reference cell area RCA of FIG. 10 may include the first and second reference cells (RC1 and RC2 of FIG. 3) and the reference resistor circuit 231.

The reference resistor circuit 231 may include a first reference resistor circuit 2311 and a second reference resistor circuit 2312. The first reference resistor circuit 2311 may include the first reference resistor Rref_M and a first switch SW1 connected together in series. The second reference resistor circuit 2312 may include the second reference resistor Rref_O and a second switch SW2 connected together in series. Specifically, a first terminal of the first reference resistor Rref_M may be connected to a first terminal of the second reference resistor Rref_O. The first terminals of the first and second reference resistors Rref_M, Rref_O may be connected to ground or another voltage source (e.g., VSS). A second terminal of the first reference resistor Rref_M may be connected to a first terminal of the first switch SW1, and a second terminal of the first switch SW1 may be connected to the reference bit line RBL. A second terminal of the second reference resistor Rref_O may be connected to a first terminal of the second switch SW2, and a second terminal of the second switch SW2 may be connected to the reference bit line RBL.

The first reference resistor Rref_M may have the first reference resistance Rref_M. The second reference resistor Rref_O may have one selected from the above-described (2-1)-st reference resistance Rref_O_1 or the (2-2)-nd reference resistance Rref_O_2.

The reference resistor circuit 231 may be configured to have a resistance value varying based on a control signal from the control logic (80 of FIG. 2) and a signal from the row decoder (20 of FIG. 2).

The control logic (80 of FIG. 2) may generate a control signal varying based on which operation the nonvolatile memory performs among the read operation of the memory unit cell MC and the read operation of the OTP unit cell OTPC.

When the read operation of the memory unit cell MC is to be performed, the row decoder (20 of FIG. 2) may select an address of the word line corresponding to the memory unit cell MC. Based on the selected word line, the control logic 80 of FIG. 2 may generate a first control signal that controls a resistance of the reference resistor circuit 231 to be equal to the first reference resistance Rref_M. In response to the first control signal, the first switch SW1 may be turned on, so that the first reference resistor Rref_M may be connected to the reference bit line RBL.

Alternatively, when the read operation of the OTP unit cell OTPC is to be performed, the row decoder (20 of FIG. 2) may select an address of a word line corresponding to the OTP unit cell OTPC. Based on the selected word line, the control logic (80 of FIG. 2) may generate a second control signal for controlling the resistance of the reference resistor circuit 231 to be equal to the (2-1)-st reference resistance Rref_O_1 or the (2-2)-nd reference resistance Rref_O_2. In response to the second control signal, the second switch SW2 may be turned on, so that the second reference resistor Rref_O may be connected to the reference bit line RBL.

That is, depending on the selected word line, the first reference resistor Rref_M or the second reference resistor Rref_O may be selectively connected to the reference bit line RBL. The resistance value of the first reference resistor Rref_M or that of the second reference resistor Rref_O may be selectively provided to generate a reference voltage V ref of a sense amplifier SA as a function thereof.

The sensing circuit 50 may include the sense amplifier SA and first and second current sources. The first current source providing a first current IS1 may be connected to a first node N1 of the sense amplifier SA, and the second current source providing a second current IS2 may be connected to a second node N2 of the sense amplifier SA. The first and second current sources may provide the same current.

The sense amplifier SA may detect and amplify the difference between a read voltage V read provided from the data cell area DCA and the reference voltage V ref provided from the reference cell area RCA. An amplified voltage difference (i.e., the difference between the read voltage V read and the reference voltage V ref) may be output as an output voltage VOUT of the sense amplifier SA and may be used to determine the data read from the data cell area DCA. In this case, the sense amplifier SA may operate as a voltage sensing amplifier.

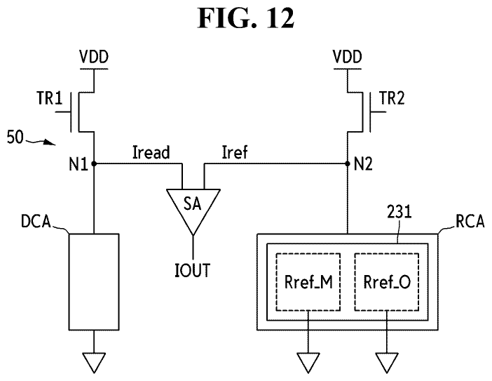

FIG. 12 is a schematic diagram for illustrating a sensing circuit according to some embodiments.

Referring to FIG. 12, the sensing circuit 50 may include first and second transistors TR1 and TR2 configured to apply a fixed voltage to nodes N1 and N2, respectively, unlike FIG. 10. In this case, the sense amplifier SA may operate as a current sensing amplifier that detects and amplifies a difference between a read current Iread provided from the data cell area DCA and a reference current Iref provided from the reference cell area RCA. The amplified current difference may be output as output current IOUT.

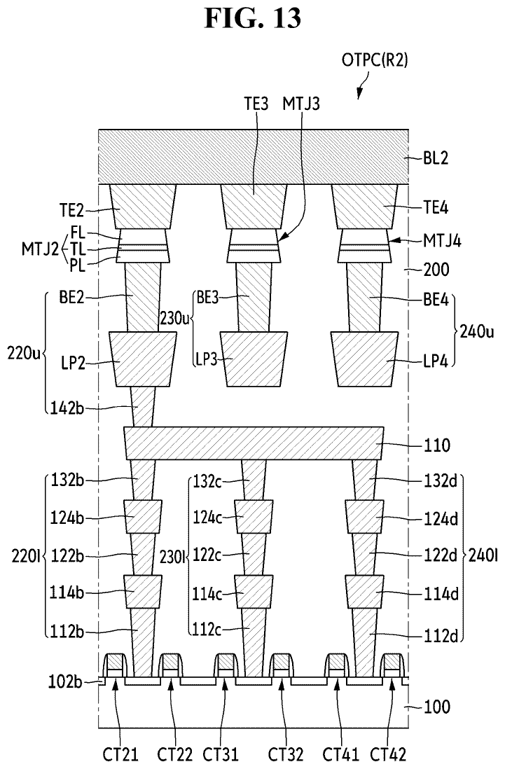

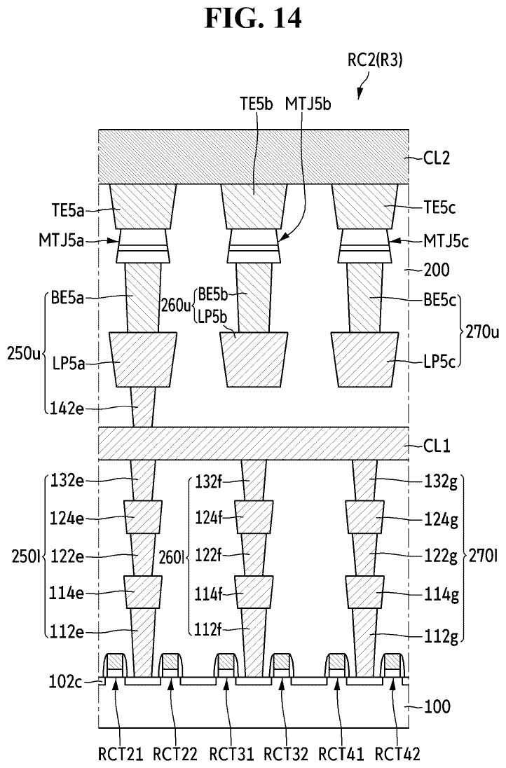

FIG. 13 and FIG. 14 are example schematic cross-sectional views of a memory device according to some embodiments.

FIG. 13 is an example cross-sectional view of a portion including one OTP unit cell OTPC connected to one bit line in FIG. 3. For convenience of illustration, the source line of FIG. 3 is omitted in FIG. 13. For convenience of the descriptions, the contents repeated with those as described above using FIG. 1 to FIG. 12 are briefly set forth or the description thereof is omitted.

Referring to FIG. 13, in some embodiments, the connection wiring 110 may be formed at the same vertical level as that of the (3-1)-st wiring 134a of FIG. 4 from the substrate 100. That is, under the second to fourth magnetic tunnel junction elements MT2, MTJ3, and MT4, the wirings disposed at the same vertical level as a vertical level of the (3-1)-st wiring (134a of FIG. 4) may be directly connected to each other.

In each of the area between the third magnetic tunnel junction element MTJ3 and the connection wiring 110, and the area between the fourth magnetic tunnel junction element MTJ4 and the connection wiring 110, a via at the same vertical level as a vertical level of the (4-2)-nd via 142b may be omitted, so that the third and fourth magnetic tunnel junction elements MTJ3 and MTJ4 may be electrically isolated from the connection wiring 110.

The first lower wiring structure 220l may include, for example, the (1-2)-nd via 112b, the (1-2)-nd wiring 114b, the (2-2)-nd via 122b, the (2-2)-nd wiring 124b, and the (3-2)-nd via 132b sequentially stacked on the substrate 100 in the vertical direction. The second lower wiring structure 230l may include, for example, the (1-3)-rd via 112c, the (1-3)-rd wiring 114c, the (2-3)-rd via 122c, the (2-3)-rd wiring 124c, and the (3-3)-rd via 132c sequentially stacked on the substrate 100 in the vertical direction. The third lower wiring structure 240l may include, for example, the (1-4)-th via 112d, the (1-4)-th wiring 114d, the (2-4)-th via 122d, the (2-4)-th wiring 124d, and the (3-4)-th via 132d sequentially stacked on the substrate 100 in the vertical direction. Each of the (2-2)-nd to (2-4)-th vias 122b, 122c, and 122d may connect each of the (1-2)-nd to (1-4)-th wirings 114b, 114c, and 114d and each of the (2-2)-nd to (2-4)-th wirings 124b, 124c, and 124d to each other. Each of the (3-2)-nd to (3-4)-th vias 132b, 132c, and 132d may connect each of the (2-2)-nd to (2-4)-th wirings 124b, 124c, and 124d to the connection wiring 110.

The first upper wiring structure 220u may include, for example, the (4-2)-nd via 142b, the second landing pad LP2, and the second lower electrode BE2 sequentially stacked on the connection wiring 110 in the vertical direction. The (4-2)-nd via 142b may connect the connection wiring 110 and the second landing pad LP2 to each other. The second upper wiring structure 230u may include, for example, the third landing pad LP3 and the third lower electrode BE3 sequentially stacked on the connection wiring 110 in the vertical direction. The third landing pad LP3 may be spaced apart from the connection wiring 110. The third landing pad LP3 may not be in direct contact with the connection wiring 110. The third upper wiring structure 240u may include the fourth landing pad LP4 and the fourth lower electrode BE4 sequentially stacked on the connection wiring 110. The fourth landing pad LP4 may be spaced apart from the connection wiring 110. The fourth landing pad LP4 may not be in direct contact with the connection wiring 110.

FIG. 14 is an example schematic cross-sectional view of a magnetic memory device according to some embodiments. FIG. 14 is an example cross-sectional view of a portion including one reference cell RC2 connected to one reference bit line in FIG. 3. For convenience of illustration, the reference source line of FIG. 3 is omitted in FIG. 14. For convenience of the descriptions, the contents repeated with those as described above using FIG. 1 to FIG. 13 are briefly set forth or the description thereof is omitted.

Referring to FIG. 14, in some embodiments, the first conductive line CL1 may be formed at the same vertical level as that of the (3-1)-st wiring (134a in FIG. 4) from the substrate 100. That is, under the 5a-th to 5c-th magnetic tunnel junction elements MTJ5a, MTJ5b, and MTJ5c, the wirings disposed at the same vertical level as a vertical level of the (3-1)-st wiring (134a in FIG. 4) may be directly connected to each other.

In each of an area between the 5b-th magnetic tunnel junction element MTJ5b and the first conductive line CL1, and an area between the 5c-th magnetic tunnel junction element MTJ5c and the first conductive line CL1, the via at the same vertical level as a vertical level of the (4-2)-nd via (142b in FIG. 4) may be omitted.

The fourth lower wiring structure 250l may include, for example, the (1-5)-th via 112e, the (1-5)-th wiring 114e, the (2-5)-th via 122e, the (2-5)-th wiring 124e, and the (3-5)-th via 132e sequentially stacked on the substrate 100 in the vertical direction. The fifth lower wiring structure 260l may include, for example, the (1-6)-th via 112f, the (1-6)-th wiring 114f, the (2-6)-th via 122f, the (2-6)-th wiring 124f, and the (3-6)-th via 132f sequentially stacked on the substrate 100 in the vertical direction. The sixth lower wiring structure 270l may include, for example, the (1-7)-th via 112g, the (1-7)-th wiring 114g, the (2-7)-th via 122g, the (2-7)-th wiring 124g, and the (3-7)-th via 132g sequentially stacked on the substrate 100 in the vertical direction.

The fourth upper wiring structure 250u may include, for example, the (4-5)-th via 142e, the 5a-th landing pad LP5a, and the 5a-th lower electrode BE5a sequentially stacked on the first conductive line CL1 in the vertical direction. The (4-5)-th via 142e may electrically connect the first conductive line CL1 and the 5a-th landing pad LP5a to each other. The fifth upper wiring structure 260u may include, for example, the 5b-th landing pad LP5b and the 5b-th lower electrode BE5b sequentially stacked on the first conductive line CL1 in the vertical direction. The 5b-th landing pad LP5b may be spaced apart from the first conductive line CL1. The 5b-th landing pad LP5b may not be in direct contact with the first conductive line CL1. The sixth upper wiring structure 270u may include, for example, the 5c-th landing pad LP5c and the 5c-th lower electrode BE5c sequentially stacked on the first conductive line CL1 in the vertical direction. The 5c-th landing pad LP5c may be spaced apart from the first conductive line CL1. The 5c-th landing pad LP5c may not be in direct contact with the first conductive line CL1.

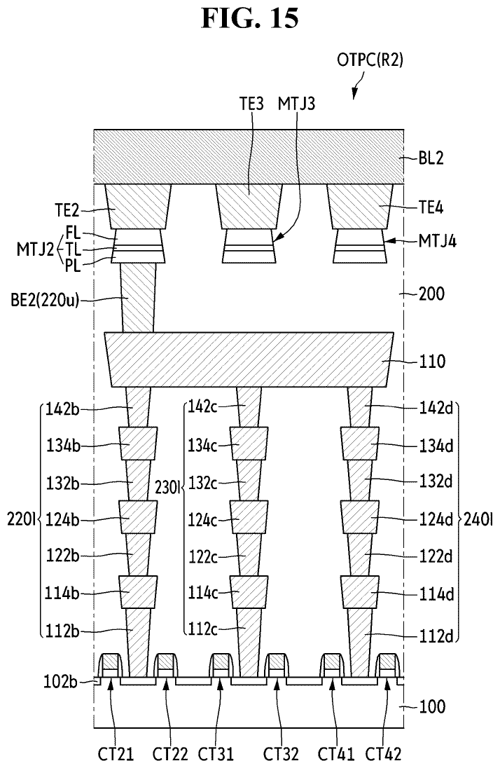

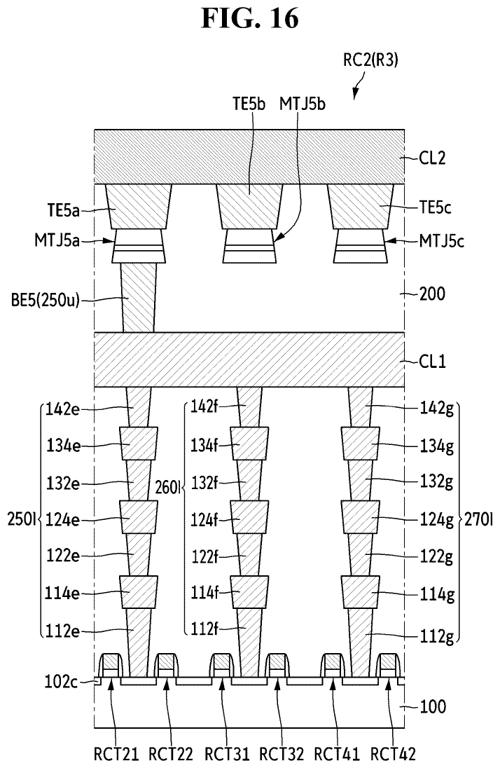

FIG. 15 and FIG. 16 are example schematic cross-sectional views of a memory device according to some embodiments.

FIG. 15 is an example cross-sectional view of a portion including one OTP unit cell OTPC connected to one bit line in FIG. 3. For convenience of illustration, the source line of FIG. 3 is omitted in FIG. 15. For convenience of the descriptions, the contents repeated with those as described above using FIG. 1 to FIG. 14 are briefly set forth or the description thereof is omitted.

Referring to FIG. 15, in some embodiments, the connection wiring 110 may be formed at the same vertical level as that of the first landing pad (LP1 of FIG. 4) from the substrate 100. That is, under the second to fourth magnetic tunnel junction elements MTJ2, MTJ3, and MTJ4, the wirings disposed at the same vertical level as a vertical level of the first landing pad (LP1 of FIG. 4) may be directly connected to each other.

In each of the area between the third magnetic tunnel junction element MTJ3 and the connection wiring 110, and the area between the fourth magnetic tunnel junction element MTJ4 and the connection wiring 110, a via at the same vertical level as a vertical level of the second lower electrode BE2 may be omitted, and therefore the third and fourth magnetic tunnel junction elements MTJ3 and MTJ4 may be electrically isolated from the connection wiring 110.

The first lower wiring structure 220l may include, for example, the (1-2)-nd via 112b, the (1-2)-nd wiring 114b, the (2-2)-nd via 122b, the (2-2)-nd wiring 124b, the (3-2)-nd via 132b, the (3-2)-nd wiring 134b, and the (4-2)-nd via 142b sequentially stacked on the substrate 100 in the vertical direction. The second lower wiring structure 230l may include, for example, the (1-3)-rd via 112c, the (1-3)-rd wiring 114c, the (2-3)-rd via 122c, the (2-3)-rd wiring 124c, the (3-3)-rd via 132c, the (3-3)-rd wiring 134b, and the (4-3)-rd via 142c sequentially stacked on the substrate 100 in the vertical direction. The third lower wiring structure 240l may include, for example, the (1-4)-th via 112d, the (1-4)-th wiring 114d, the (2-4)-th via 122d, the (2-4)-th wiring 124d, the (3-4)-th via 132d, the (3-4)-th wiring 134d, and the (4-4)-th via 142d sequentially stacked on the substrate 100 in the vertical direction. Each of the (4-2)-nd to the (4-4)-th via 142b, 142c, and 142d may connect each of the (3-2)-nd to the (3-4)-th wirings 134b, 134c, and 134d to the connection wiring 110.

The first upper wiring structure 220u may include the second lower electrode BE2. The second lower electrode BE2 may electrically connect the connection wiring 110 and the second magnetic tunnel junction element MTJ2 to each other. The second upper wiring structure (230u in FIG. 5) and the third upper wiring structure (240u in FIG. 5) may be omitted. The third magnetic tunnel junction element MTJ3 and the fourth magnetic tunnel junction element MTJ4 may be spaced apart from the connection wiring 110. The third magnetic tunnel junction element MTJ3 and the fourth magnetic tunnel junction element MTJ4 may not be in direct contact with the connection wiring 110.

Each OTP unit cell OTPC may include the second to fourth cell transistors CT21, CT22, CT31, CT32, CT41 and CT42, the connection wiring 110, the first to third lower wiring structures 220l, 230l, and 240l, the first upper wiring structure 220u, the second to fourth magnetic tunnel junction elements MTJ2, MTJ3, and MTJ4, and the second to fourth upper electrodes TE2, TE3, and TE4.

FIG. 16 is an example schematic cross-sectional view of a magnetic memory device according to some embodiments. FIG. 16 is an example cross-sectional view of a portion including one reference cell RC2 connected to one reference bit line in FIG. 3. For convenience of illustration, the reference source line of FIG. 3 is omitted in FIG. 16. For convenience of the descriptions, the contents repeated with those as described above using FIG. 1 to FIG. 15 are briefly set forth or the description thereof is omitted.

Referring to FIG. 16, in some embodiments, the first conductive line CL1 may be formed at the same vertical level as that of the first landing pad (LP1 of FIG. 4) from the substrate 100. That is, under the 5a-th to 5c-th magnetic tunnel junction elements MTJ5a, MTJ5b, and MTJ5c, the wirings disposed at the same vertical level as a vertical level of the first landing pad (LP1 of FIG. 4) may be directly connected to each other.

A via at the same vertical level as a vertical level of the second lower electrode (BE2 of FIG. 5) may be omitted in each of an area between the 5b-th magnetic tunnel junction element MTJ5b and the first conductive line CL1, and an area between the 5c-th magnetic tunnel junction element MTJ5c and the first conductive line CL1.

The fourth lower wiring structure 250l may include, for example, the (1-5)-th via 112e, the (1-5)-th wiring 114e, the (2-5)-th via 122e, the (2-5)-th wiring 124e, the (3-5)-th via 132e, the (3-5)-th wiring 134e, and the (4-5)-th via 142e sequentially stacked on the substrate 100 in the vertical direction. The fifth lower wiring structure 260l may include, for example, the (1-6)-th via 112f, the (1-6)-th wiring 114f, the (2-6)-th via 122f, the (2-6)-th wiring 124f, the (3-6)-th via 132f, the (3-6)-th wiring 134f, and the (4-6)-th via 142f sequentially stacked on the substrate 100 in the vertical direction. The sixth lower wiring structure 270l may include, for example, the (1-7)-th via 112g, the (1-7)-th wiring 114g, the (2-7)-th via 122g, the (2-7)-th wiring 124g, the (3-7)-th via 132g, the (3-7)-th wiring 134g, and the (4-7)-th via 142g sequentially stacked on the substrate 100 in the vertical direction.

The fourth upper wiring structure 250u may include the fifth lower electrode BE5. The fifth lower electrode BE5 may be disposed between the first conductive line CL1 and the 5a-th magnetic tunnel junction element MTJ5a. The second upper wiring structure (230u in FIG. 5) and the third upper wiring structure (240u in FIG. 5) may be omitted. The 5b-th magnetic tunnel junction element MTJ5b and the 5c-th magnetic tunnel junction element MTJ5c may be spaced apart from the first conductive line CL1. The 5b-th magnetic tunnel junction element MTJ5b and the 5c-th magnetic tunnel junction element MTJ5c may not be in direct contact with the first conductive line CL1.

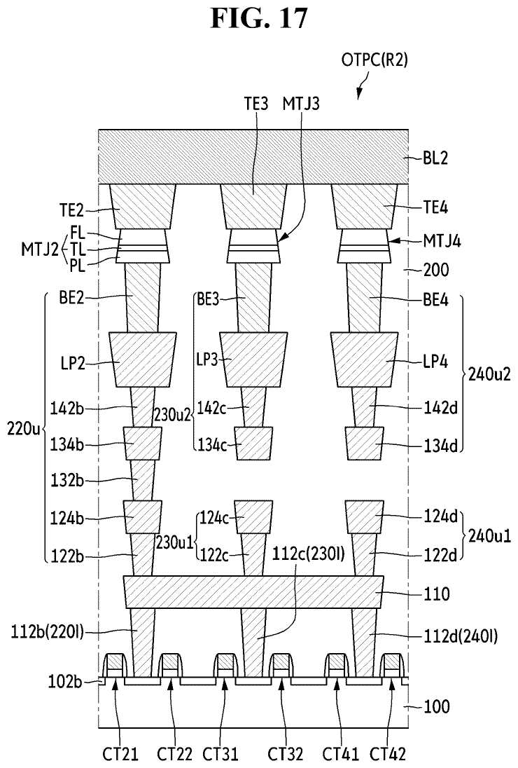

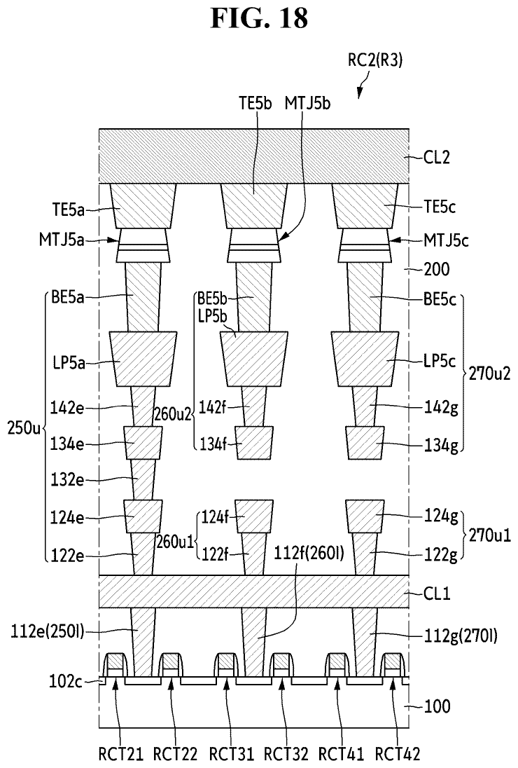

FIG. 17 and FIG. 18 are example schematic cross-sectional views of a memory device according to some embodiments.

FIG. 17 is an example cross-sectional view of a portion including one OTP unit cell OTPC connected to one bit line in FIG. 3. For convenience of illustration, the source line of FIG. 3 is omitted in FIG. 17. For convenience of the descriptions, the contents repeated with those as described above using FIG. 1 to FIG. 16 are briefly set forth or the description thereof is omitted.

Referring to FIG. 17, in some embodiments, a via at the same vertical level as a vertical level of the via that does not directly contact the connection wiring 110 may be omitted in the area between each of the third and fourth magnetic tunnel junction elements MTJ3 and MTJ4 and the connection wiring 110. For example, in each of the area between the third magnetic tunnel junction element MTJ3 and the connection wiring 110, and the area between the fourth magnetic tunnel junction element MTJ4 and the connection wiring 110, a via having the same vertical level as a vertical level of the (3-2)-nd via 132b may be omitted.

A first sub-wiring structure 230u1 and a second sub-wiring structure 230u2 may be disposed between the connection wiring 110 and the third magnetic tunnel junction element MTJ3. The first sub-wiring structure 230u1 may be electrically connected to the connection wiring 110. The second sub-wiring structure 230u2 may be electrically connected to the third magnetic tunnel junction element MTJ3. The first sub-wiring structure 230u1 and the second sub-wiring structure 230u2 may be spaced apart from each other in the vertical direction and electrically isolated from one another. The first sub-wiring structure 230u1 and the second sub-wiring structure 230u2 may not be in direct contact with each other.

The first sub-wiring structure 230u1 may include, for example, the (2-3)-rd via 122c and the (2-3)-rd wiring 124c sequentially stacked on the connection wiring 110 in the vertical direction. The second sub-wiring structure 230u2 may include, for example, the third lower electrode BE3, a third landing pad LP3, the (4-3)-rd via 142c, and the (3-3)-rd wiring 134c sequentially stacked under the third magnetic tunnel junction element MTJ3 in the vertical direction. The (2-3)-rd wiring 124c and the (3-3)-rd wiring 134c may be spaced apart from each other. The (2-3)-rd wiring 124c and the (3-3)-rd wiring 134c may not be in direct contact with each other.

A third sub-wiring structure 240u1 and a fourth sub-wiring structure 240u2 may be disposed between the connection wiring 110 and the fourth magnetic tunnel junction element MTJ4. The third sub-wiring structure 240u1 may be electrically connected to the connection wiring 110. The fourth sub-wiring structure 240u2 may be electrically connected to the fourth magnetic tunnel junction element MTJ4. The third sub-wiring structure 240u1 and the fourth sub-wiring structure 240u2 may be spaced apart from each other in the vertical direction and electrically isolated from one another. The third sub-wiring structure 240u1 and the fourth sub-wiring structure 240u2 may not be in direct contact with each other.

The third sub-wiring structure 240u1 may include, for example, the (2-4)-th via 122d and the (2-4)-th wiring 124d sequentially stacked on the connection wiring 110 in the vertical direction. The fourth sub-wiring structure 240u2 may include, for example, the fourth lower electrode BE4, the fourth landing pad LP4, the (4-4)-th via 142d, and the (3-4)-th wiring 134d sequentially stacked under the fourth magnetic tunnel junction element MTJ4 in the vertical direction. The (2-4)-th wiring 124d and the (3-4)-th wiring 134d may be spaced apart from each other. The (2-4) wiring 124d and the (3-4)-th wiring 134d may not be in direct contact with each other.

FIG. 18 is an example schematic cross-sectional view of a magnetic memory device according to some embodiments.

FIG. 18 is an example cross-sectional view of a portion including one reference cell RC2 connected to one reference bit line in FIG. 3. For convenience of illustration, the reference source line of FIG. 3 is omitted in FIG. 18. For convenience of the descriptions, the contents repeated with those as described above using FIG. 1 to FIG. 17 are briefly set forth or the description thereof is omitted.

Referring to FIG. 18, in some embodiments, a via at the same vertical level as a vertical level of the via that does not directly contact the first conductive line CL1 may be omitted in an area between each of the 5b-th and 5c-th magnetic tunnel junction elements MTJ5b, and MTJ5c and the first conductive line CL1. For example, in each of the area between the 5b-th magnetic tunnel junction element MTJ5b and the first conductive line CL1, and the area between the 5c-th magnetic tunnel junction element MTJ5c and the first conductive line CL1, a via at the same vertical level as a vertical level of the (3-2)-nd via (132b in FIG. 4) may be omitted.

A fifth sub-wiring structure 260u1 and a sixth sub-wiring structure 260u2 may be disposed between the first conductive line CL1 and the 5b-th magnetic tunnel junction element MTJ5b. The fifth sub-wiring structure 260u1 may be electrically connected to the first conductive line CL1. The sixth sub-wiring structure 260u2 may be electrically connected to the 5b-th magnetic tunnel junction element MTJ5b. The fifth sub-wiring structure 260u1 and the sixth sub-wiring structure 260u2 may be spaced apart from each other in the vertical direction and electrically isolated from one another. The fifth sub-wiring structure 260u1 and the sixth sub-wiring structure 260u2 may not be in direct contact with each other.

The fifth sub-wiring structure 260u1 may include, for example, the (2-6)-th via 122f and the (2-6)-th wiring 124f sequentially stacked on the first conductive line CL1 in the vertical direction. The sixth sub-wiring structure 260u2 may include, for example, the 5b-th lower electrode BE5b, the 5b-th landing pad P5b, the (4-6)-th via 142f, and the (3-6)-th wiring 134f sequentially stacked under the 5b-th magnetic tunnel junction element MTJ5b in the vertical direction. The (2-6)-th wiring 124f and the (3-6)-th wiring 134f may be spaced from each other. The (2-6)-th wiring 124f and the (3-6)-th wiring 134f may not be in direct contact with each other.

A seventh sub-wiring structure 270u1 and an eighth sub-wiring structure 270u2 may be disposed between the first conductive line CL1 and the 5c-th magnetic tunnel junction element MTJ5c. The seventh sub-wiring structure 270u1 may be electrically connected to the first conductive line CL1. The eighth sub-wiring structure 270u2 may be electrically connected to the 5c-th magnetic tunnel junction element MTJ5c. The seventh sub-wiring structure 270u1 and the eighth sub-wiring structure 270u2 may be spaced apart from each other in the vertical direction and electrically isolated from one another. The seventh sub-wiring structure 270u1 and the eighth sub-wiring structure 270u2 may not be in direct contact with each other.

The seventh sub-wiring structure 270u1 may include, for example, the (2-7)-th via 122g and the (2-7)-th wiring 124g sequentially stacked on the first conductive line CL1 in the vertical direction. The eighth sub-wiring structure 270u2 may include, for example, the 5c-th lower electrode BE5c, the 5c-th landing pad LP5c, the (4-7)-th via 142g, and the (3-7)-th wiring 134g sequentially stacked under the 5c-th magnetic tunnel junction element MTJ5c in the vertical direction. The (2-7)-th wiring 124g and the (3-7)-th wiring 134g may be spaced apart from each other. The (2-7)-th wiring 124g and the (3-7)-th wiring 134g may not be in direct contact with each other.

In one example, although not specifically illustrated, in some embodiments, the OTP unit cells OTPC may be connected to a specific bit line BL. For example, the OTP unit cells OTPC may be connected to a bit line BL disposed in the peripheral area of the memory cell array 10.

In this case, only memory unit cells MC may be connected to one bit line BL, or only OTP unit cells OTPC may be connected thereto. Alternatively, memory unit cells MC and OTP unit cells OTPC may be connected to one word line WL.

In this case, in setting the second reference resistance Rref_O used during the read operation of the OTP unit cell OTPC, the method of setting the second reference resistance Rref_O as described using FIG. 1 to FIG. 12 may be used. For example, the second reference resistance Rref_O may be set using the first edge resistance value Rref_E1 detected from the resistance distribution Rp of the OTP unit cell OTPC or the first reference resistance Rref_M for reading the data from the memory unit cell MC.

Furthermore, although not specifically illustrated, in some embodiments, the memory unit cells MC and the OTP unit cells OTPC may be connected to different input/output circuits.

In this case, the memory cell array (10 in FIG. 2) may include a plurality of memory cell arrays. Each memory cell array may be connected to each input/output circuit and each column decoder.

A first memory cell array (not shown) may include the OTP unit cells OTPC, and a second memory cell array (not shown) may include the memory unit cells MC. Only OTP unit cells OTPC may be connected to the bit line BL of the first memory cell array (not shown), and only memory unit cells MC may be connected to the bit line BL of the second memory cell array (not shown). The memory unit cells MC and the OTP unit cells OTPC may be connected to one word line WL.

In this case, in setting the second reference resistance Rref_O used during the read operation of the OTP unit cell OTPC, the method for setting the second reference resistance Rref_O as described using FIG. 1 to FIG. 12 may be used. For example, the second reference resistance Rref_O may be set using the first edge resistance value Rref_E1 detected from the resistance distribution Rp of the OTP unit cell OTPC or the first reference resistance Rref_M for reading the data from the memory unit cell MC.

Furthermore, although not specifically illustrated, in some embodiments, four columns of memory unit cells MC may share one source line SL. Four columns of OTP unit cells OTPC may share one source line SL.

In this case, in setting the second reference resistance Rref_O used during the read operation of the OTP unit cell OTPC, the method for setting the second reference resistance Rref_O as described using FIG. 1 to FIG. 12 may be used. For example, the second reference resistance Rref_O may be set using the first edge resistance value Rref_E1 detected from the resistance distribution Rp of the OTP unit cell OTPC or the first reference resistance Rref_M for reading the data from the memory unit cell MC.

Furthermore, although not specifically illustrated, in some embodiments, the memory unit cell MC may have a structure in which one cell transistor CT11 is connected to one magnetic tunnel junction element MTJ1. The OTP unit cell OTPC may have a structure in which three cell transistors CT21, CT31, and CT41 are connected to one magnetic tunnel junction element MTJ2.

In this case, in setting the second reference resistance Rref_O used during the read operation of the OTP unit cell OTPC, the method for setting the second reference resistance Rref_O as described using FIG. 1 to FIG. 12 may be used. For example, the second reference resistance Rref_O may be set using the first edge resistance value Rref_E1 detected from the resistance distribution Rp of the OTP unit cell OTPC or the first reference resistance Rref_M for reading the data from the memory unit cell MC.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A memory device, comprising:
a nonvolatile memory including a memory cell array; and
a controller configured to control the nonvolatile memory,
wherein the memory cell array includes:
a memory cell including a first magnetic tunnel junction element;
an OTP (One-Time-Programmable) cell including a second magnetic tunnel junction element; and
a reference cell electrically connected to a first reference resistor for reading data from the memory cell or a second reference resistor for reading data from the OTP cell,
wherein the controller is configured to set a second reference resistance of the second reference resistor, based on a first edge resistance value detected from a resistance distribution of OTP cells comprising the OTP cell or based on a first reference resistance of the first reference resistor.

2. The memory device of claim 1, wherein the second reference resistance is set to a resistance value offset from the first edge resistance value by a first offset.

3. The memory device of claim 2, wherein the first offset is variable based on the first edge resistance value.

4. The memory device of claim 1, wherein the second reference resistance is set to a resistance between a resistance distribution of the second magnetic tunnel junction element in a first state and a resistance distribution of the second magnetic tunnel junction element in a second state different from the first state.

5. The memory device of claim 1, wherein the second reference resistance is set to a resistance value offset from the first reference resistance by a second offset.

6. The memory device of claim 5, wherein the second offset is variable based on the first reference resistance.

7. The memory device of claim 1, wherein the second reference resistance is set to a resistance value between a resistance distribution of the second magnetic tunnel junction element in a first state and a resistance distribution of the first magnetic tunnel junction element in a second state different from the first state.

8. The memory device of claim 1, wherein the nonvolatile memory further includes a row decoder configured to select each of a word line to be connected to the memory cell and a word line to be connected to the OTP cell.

9. The memory device of claim 8, wherein the nonvolatile memory further includes:
first and second current sources; and
a sense amplifier configured to detect and amplify a difference between a read voltage provided from each of the memory cell and the OTP cell and a reference voltage provided from the reference cell,
wherein the first reference resistance or the second reference resistance is provided to the sense amplifier as a function of the word line selected to be connected to the memory cell and the word line selected to be connected to the OTP cell.

10. The memory device of claim 8, wherein the nonvolatile memory further includes:
first and second transistors; and
a sense amplifier configured to detect and amplify a difference between a read current provided from each of the memory cell and the OTP cell and a reference current provided from the reference cell,
wherein the first reference resistance or the second reference resistance is provided to the sense amplifier as a function of the word line selected to be connected to the memory cell and the word line selected to be connected to the OTP cell.

11. A memory device, comprising:
a nonvolatile memory including a memory cell array; and
a controller connected to the nonvolatile memory,
wherein the memory cell array includes memory cells including first magnetic tunnel junction elements, and one-time-programmable (OTP) cells including second magnetic tunnel junction elements,
wherein the controller includes a reference resistance setting module configured to set a reference resistance for reading data of the memory cell array,
wherein the reference resistance setting module is configured:
to detect a first resistance value from a resistance distribution of the OTP cells programmed to the first state;
to receive a second resistance value from a resistance distribution of the memory cells programmed to the first state and a resistance distribution of the memory cells programmed to a second state different from the first state; and
to set a reference resistance for reading data of the OTP cells, based on the first resistance value or the second resistance value.

12. The memory device of claim 11, wherein the reference resistance setting module is further configured to set a first reference resistance offset from the first resistance value by a first offset as the reference resistance for reading the data of the OTP cells.

13. The memory device of claim 12, wherein the first offset is a variable based on the first resistance value.

14. The memory device of claim 11, wherein the reference resistance setting module is further configured to set a second reference resistance offset from the second resistance value by a second offset as the reference resistance for reading the data of the OTP cells.

15. The memory device of claim 14, wherein the second offset is a variable based on the second resistance value.

16. The memory device of claim 11, wherein the reference resistance is a fixed reference resistance.

17. The memory device of claim 11, wherein the controller further includes an error correction code module,
wherein the error correction code module is configured to correct fail bits of the OTP cells.

18. A memory device, comprising:
a nonvolatile memory including a memory cell array; and
a controller configured to control the nonvolatile memory,
wherein the memory cell array includes:
a memory cell including a first magnetic tunnel junction element electrically connected to a first bit line, and a first cell transistor electrically connecting the first magnetic tunnel junction element and a first source line to each other;
a one-time-programmable (OTP) cell including second, third and fourth magnetic tunnel junction elements electrically connected to a second bit line, and second, third and fourth cell transistors electrically connecting a second source line and the second magnetic tunnel junction element to each other; and
a reference cell connected to a first reference resistor having a first reference resistance for reading data from the memory cell or a second reference resistor having a second reference resistance for reading data from the OTP cell,
wherein the third and fourth magnetic tunnel junction elements are electrically isolated from the second, third and fourth cell transistors,
wherein the controller includes a reference resistance setting module configured to set the second reference resistance,
wherein the reference resistance setting module is configured to set the second reference resistance, based on a first edge resistance value detected from a resistance distribution of OTP cells comprising the OTP cell or based on the first reference resistance.

19. The memory device of claim 18, wherein a gate of the first cell transistor is connected to a first word line,
wherein a gate of the second cell transistor is connected to a second word line,
wherein a gate of the third cell transistor and a gate of the fourth cell transistor are connected to a third word line different from the second word line.

20. The memory device of claim 18, wherein the nonvolatile memory further includes a row decoder configured to select each of a word line to be connected to the memory cell and a word line to be connected to the OTP cell, and
wherein the first reference resistor or the second reference resistor is electrically connected to the second bit line as a function of the word line selected to be connected to the memory cell and the word line selected to be connected to the OTP cell.
